(19) United States
(12) Patent Application Publication
(10) Pub. No.: US 2024/0099127 A1
(43) Pub. Date: Mar. 21, 2024

(54) ORGANIC ELECTROLUMINESCENT ELEMENT AND ELECTRONIC DEVICE

(71) Applicant: IDEMITSU KOSAN CO.,LTD., Tokyo (JP)

(72) Inventors: Tasuku HAKETA, Sodegaura-shi (JP); Kazuki NISHIMURA, Sodegaura-shi (JP)

(73) Assignee: IDEMITSU KOSAN CO.,LTD., Tokyo (JP)

(21) Appl. No.: 17/766,214

(22) PCT Filed: Sep. 28, 2020
(86) PCT No.: PCT/JP2020/036550

§ 371 Date: Apr. 1, 2022

(30) Foreign Application Priority Data
Oct. 4, 2019 (JP) 2019-184170

(51) Int. Cl. H10K 85/60; H10K 50/15

(52) U.S. Cl. CPC H10K 85/633; H10K 50/15; H10K 85/622; H10K 85/6572; H10K 85/6574; H10K 85/6576

(57) ABSTRACT

An organic electroluminescence device having: a cathode, an anode, and an organic layer disposed between the cathode and the anode, wherein the organic layer includes an emitting layer and a first layer, the first layer is disposed between the anode and the emitting layer, and the first layer contains a first hole-transporting material represented by the following formula (1) and a second hole-transporting material represented by the following formula (11):

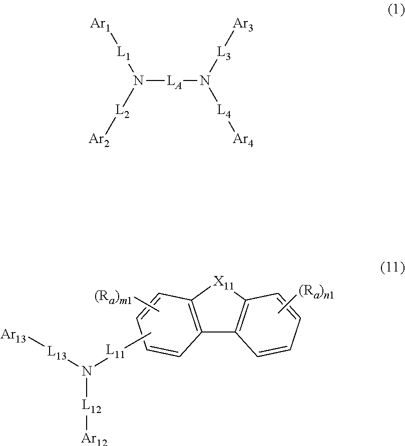

### TECHNICAL FIELD

The invention relates to an organic electroluminescence device and an electronic apparatus.

### BACKGROUND ART

When voltage is applied to an organic electroluminescence device (hereinafter, referred to as an organic EL device), holes and electrons are injected into an emitting layer from an anode and a cathode, respectively. Then, thus injected holes and electrons are recombined in the emitting layer, and excitons are formed therein.

The organic EL device includes the emitting layer between the anode and the cathode. Further, the organic EL device has a stacked structure including an organic layer such as a hole-injecting layer, a hole-transporting layer, an electron-injecting layer, and an electron-transporting layer in several cases.

Patent Document 1 discloses an organic EL device having a mixture of two or more materials in a hole-transporting layer.

Patent Document 2 discloses an organic EL device having a hole-transporting layer containing a composition composed of two or more kinds of compounds having similar structures to each other.

### RELATED ART DOCUMENTS

### Patent Documents

[Patent Document 1] WO2011/110262

[Patent Document 2] US2017/0317289

### SUMMARY OF THE INVENTION

An object of the invention is to provide an organic EL device having a low driving voltage, a high luminous efficiency, and a long lifetime.

According to the invention, the following organic electroluminescence device and electronic apparatus are provided.
1. An organic electroluminescence device comprising a cathode, an anode, and an organic layer disposed between the cathode and the anode, wherein

the organic layer comprises an emitting layer and a first layer,

the first layer is disposed between the anode and the emitting layer, and

the first layer comprises a first hole-transporting material represented by the following formula (1) and a second hole-transporting material represented by the following formula (11):

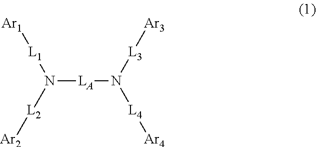

wherein in the formula (1),

L_{A} is
a substituted or unsubstituted arylene group including 6 to 50 ring carbon atoms, or
a substituted or unsubstituted divalent heterocyclic group including 5 to 50 ring atoms;

L₁ to L₄ are independently a single bond or a linking group;

when each of L₁ to L₄ is a linking group, the linking group is
a substituted or unsubstituted arylene group including 6 to 50 ring carbon atoms, or
a substituted or unsubstituted divalent heterocyclic group including 5 to 50 ring atoms; and

Ar₁ to Ar₄ are independently
a substituted or unsubstituted aryl group including 6 to 50 ring carbon atoms, or
a substituted or unsubstituted monovalent heterocyclic group including 5 to 50 ring atoms;

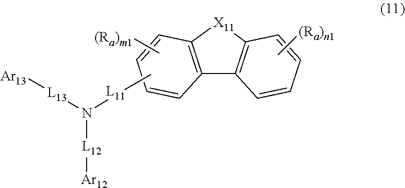

wherein in the formula (11),

L₁₁ to L₁₃ are independently a single bond or a linking group;

when each of L₁₁ to L₁₃ is a linking group, the linking group is
a substituted or unsubstituted arylene group including 6 to 50 ring carbon atoms, or
a substituted or unsubstituted divalent heterocyclic group including 5 to 50 ring atoms;

each set of L₁₁ and L₁₂, L₁₁ and L₁₃, L₁₁ and Ar₁₂, and L₁₁ and Ar₁₃ does not form a heterocycle containing N by bonding with each other;

Ar₁₂ and Ar₁₃ are independently
a substituted or unsubstituted aryl group including 6 to 50 ring carbon atoms, or
a substituted or unsubstituted monovalent heterocyclic group including 5 to 50 ring atoms;

X₁₁ is O, S, or C(R₁₁)(R₁₂);

R₁₁ and R₁₂ form a substituted or unsubstituted, saturated or unsaturated ring by bonding with each other, or do not form the ring;

R₁₁ and R₁₂ which do not form the ring are independently a hydrogen atom,
a substituted or unsubstituted aryl group including 6 to 50 ring carbon atoms, or
a substituted or unsubstituted monovalent heterocyclic group including 5 to 60 ring atoms;

Rₐ is
a substituted or unsubstituted alkyl group including 1 to 50 carbon atoms,
a substituted or unsubstituted aryl group including 6 to 50 ring carbon atoms, or
a substituted or unsubstituted monovalent heterocyclic group including 5 to 50 ring atoms;

m1 is an integer of 0 to 3; when m1 is 2 or more, two or more Rₐ's are the same as or different from each other; and

n1 is an integer of 0 to 4; and when n1 is 2 or more, two or more Rₐ's are the same as or different from each other.
2. An electronic apparatus, equipped with the organic electroluminescence device according to 1.

According to the invention, an organic EL device having a low driving voltage, a high luminous efficiency, and a long lifetime can be provided.

### BRIEF DESCRIPTION OF THE DRAWINGS

FIG. 1 is a diagram showing a schematic configuration of an organic EL device according to one embodiment of the invention.

### MODE FOR CARRYING OUT THE INVENTION

### Definition

In this specification, a hydrogen atom includes its isotopes different in the number of neutrons, namely, a protium, a deuterium and a tritium.

In this specification, at a bondable position in a chemical formula where a symbol such as “R”, or “D” representing a deuterium atom is not indicated, a hydrogen atom, that is, a protium atom, a deuterium atom or a tritium atom is bonded.

In this specification, the number of ring carbon atoms represents the number of carbon atoms forming a subject ring itself among the carbon atoms of a compound having a structure in which atoms are bonded in a ring form (for example, a monocyclic compound, a fused ring compound, a cross-linked compound, a carbocyclic compound, or a heterocyclic compound). When the subject ring is substituted by a substituent, the carbon contained in the substituent is not included in the number of ring carbon atoms. The same shall apply to “the number of ring carbon atoms” described below, unless otherwise specified. For example, a benzene ring has 6 ring carbon atoms, a naphthalene ring includes 10 ring carbon atoms, a pyridine ring includes 5 ring carbon atoms, and a furan ring includes 4 ring carbon atoms. Further, for example, a 9,9-diphenylfluorenyl group includes 13 ring carbon atoms, and a 9,9′-spirobifluorenyl group includes 25 ring carbon atoms.

When a benzene ring is substituted by, for example, an alkyl group as a substituent, the number of carbon atoms of the alkyl group is not included in the number of ring carbon atoms of the benzene ring. Therefore, the number of ring carbon atoms of the benzene ring substituted by the alkyl group is 6. When a naphthalene ring is substituted by, for example, an alkyl group as a substituent, the number of carbon atoms of the alkyl group is not included in the number of ring carbon atoms of the naphthalene ring. Therefore, the number of ring carbon atoms of the naphthalene ring substituted by the alkyl group is 10.

In this specification, the number of ring atoms represents the number of atoms forming a subject ring itself among the atoms of a compound having a structure in which atoms are bonded in a ring form (for example, the structure includes a monocyclic ring, a fused ring and a ring assembly) (for example, a monocyclic compound, a fused ring compound, a cross-linked compound, a carbocyclic compound and a heterocyclic compound). The number of ring atoms does not include atoms which do not form the ring (for example, a hydrogen atom which terminates a bond of the atoms forming the ring), or atoms contained in a substituent when the ring is substituted by the substituent. The same shall apply to “the number of ring atoms” described below, unless otherwise specified. For example, the number of atoms of a pyridine ring is 6, the number of atoms of a quinazoline ring is 10, and the number of a furan ring is 5. For example, hydrogen atoms bonded to a pyridine ring and atoms constituting a substituent substituted on the pyridine ring are not included in the number of ring atoms of the pyridine ring. Therefore, the number of ring atoms of a pyridine ring with which a hydrogen atom or a substituent is bonded is 6. For example, hydrogen atoms and atoms constituting a substituent which are bonded with a quinazoline ring is not included in the number of ring atoms of the quinazoline ring. Therefore, the number of ring atoms of a quinazoline ring with which a hydrogen atom or a substituent is bonded is 10.

In this specification, “XX to YY carbon atoms” in the expression “a substituted or unsubstituted ZZ group including XX to YY carbon atoms” represents the number of carbon atoms in the case where the ZZ group is unsubstituted by a substituent, and does not include the number of carbon atoms of a substituent in the case where the ZZ group is substituted by the substituent. Here, “YY” is larger than “XX”, and “XX” means an integer of 1 or more and “YY” means an integer of 2 or more.

In this specification, “XX to YY atoms” in the expression “a substituted or unsubstituted ZZ group including XX to YY atoms” represents the number of atoms in the case where the ZZ group is unsubstituted by a substituent, and does not include the number of atoms of a substituent in the case where the ZZ group is substituted by the substituent. Here, “YY” is larger than “XX”, and “XX” means an integer of 1 or more and “YY” means an integer of 2 or more.

In this specification, the unsubstituted ZZ group represents the case where the “substituted or unsubstituted ZZ group” is a “ZZ group unsubstituted by a substituent”, and the substituted ZZ group represents the case where the “substituted or unsubstituted ZZ group” is a “ZZ group substituted by a substituent”.

In this specification, a term “unsubstituted” in the case of “a substituted or unsubstituted ZZ group” means that hydrogen atoms in the ZZ group are not substituted by a substituent. Hydrogen atoms in a term “unsubstituted ZZ group” are a protium atom, a deuterium atom, or a tritium atom.

In this specification, a term “substituted” in the case of “a substituted or unsubstituted ZZ group” means that one or more hydrogen atoms in the ZZ group are substituted by a substituent. Similarly, a term “substituted” in the case of “a BB group substituted by an AA group” means that one or more hydrogen atoms in the BB group are substituted by the AA group.

### Substituent as Described in this Specification

Hereinafter, the substituent described in this specification will be explained.

The number of ring carbon atoms of the “unsubstituted aryl group” described in this specification is 6 to 50, preferably 6 to 30, and more preferably 6 to 18, unless otherwise specified.

The number of ring atoms of the “unsubstituted heterocyclic group” described in this specification is 5 to 50, preferably 5 to 30, and more preferably 5 to 18, unless otherwise specified.

The number of carbon atoms of the “unsubstituted alkyl group” described in this specification is 1 to 50, preferably 1 to 20, and more preferably 1 to 6, unless otherwise specified.

The number of carbon atoms of the “unsubstituted alkenyl group” described in this specification is 2 to 50, preferably 2 to 20, and more preferably 2 to 6, unless otherwise specified.

The number of carbon atoms of the “unsubstituted alkynyl group” described in this specification is 2 to 50, preferably 2 to 20, and more preferably 2 to 6, unless otherwise specified.

The number of ring carbon atoms of the “unsubstituted cycloalkyl group” described in this specification is 3 to 50, preferably 3 to 20, and more preferably 3 to 6, unless otherwise specified.

The number of ring carbon atoms of the “unsubstituted arylene group” described in this specification is 6 to 50, preferably 6 to 30, and more preferably 6 to 18, unless otherwise specified.

The number of ring atoms of the “unsubstituted divalent heterocyclic group” described in this specification is 5 to 50, preferably 5 to 30, and more preferably 5 to 18, unless otherwise specified.

The number of carbon atoms of the “unsubstituted alkylene group” described in this specification is 1 to 50, preferably 1 to 20, and more preferably 1 to 6, unless otherwise specified.

### Substituted or Unsubstituted Aryl Group

Specific examples of the “substituted or unsubstituted aryl group” described in this specification (specific example group G1) include the following unsubstituted aryl groups (specific example group G1A), substituted aryl groups (specific example group G1B), and the like. (Here, the unsubstituted aryl group refers to the case where the “substituted or unsubstituted aryl group” is an “aryl group unsubstituted by a substituent”, and the substituted aryl group refers to the case where the “substituted or unsubstituted aryl group” is an “aryl group substituted by a substituent”.). In this specification, in the case where simply referred as an “aryl group”, it includes both a “unsubstituted aryl group” and a “substituted aryl group.”

The “substituted aryl group” means a group in which one or more hydrogen atoms of the “unsubstituted aryl group” are substituted by a substituent. Specific examples of the “substituted aryl group” include, for example, groups in which one or more hydrogen atoms of the “unsubstituted aryl group” of the following specific example group G1A are substituted by a substituent, the substituted aryl groups of the following specific example group G1B, and the like. It should be noted that the examples of the “unsubstituted aryl group” and the examples of the “substituted aryl group” enumerated in this specification are mere examples, and the “substituted aryl group” described in this specification also includes a group in which a hydrogen atom bonded with a carbon atom of the aryl group itself in the “substituted aryl group” of the following specific group G1B is further substituted by a substituent, and a group in which a hydrogen atom of a substituent in the “substituted aryl group” of the following specific group G1B is further substituted by a substituent.

### Unsubstituted Aryl Group (Specific Example group G1A)

a phenyl group,

a p-biphenyl group,

a m-biphenyl group,

an o-biphenyl group,

a p-terphenyl-4-yl group,

a p-terphenyl-3-yl group,

a p-terphenyl-2-yl group,

a m-terphenyl-4-yl group,

a m-terphenyl-3-yl group,

a m-terphenyl-2-yl group,

an o-terphenyl-4-yl group,

an o-terphenyl-3-yl group,

an o-terphenyl-2-yl group,

a 1-naphthyl group,

a 2-naphthyl group,

an anthryl group,

a benzanthryl group,

a phenanthryl group,

a benzophenanthryl group,

a phenalenyl group,

a pyrenyl group,

a chrysenyl group,

a benzochrysenyl group,

a triphenylenyl group,

a benzotriphenylenyl group,

a tetracenyl group,

a pentacenyl group,

a fluorenyl group,

a 9,9′-spirobifluorenyl group,

a benzofluorenyl group,

a dibenzofluorenyl group,

a fluoranthenyl group,

a benzofluoranthenyl group,

a perylenyl group, and

a monovalent aryl group derived by removing one hydrogen atom from the ring structures represented by any of the following general formulas (TEMP-1) to (TEMP-15).

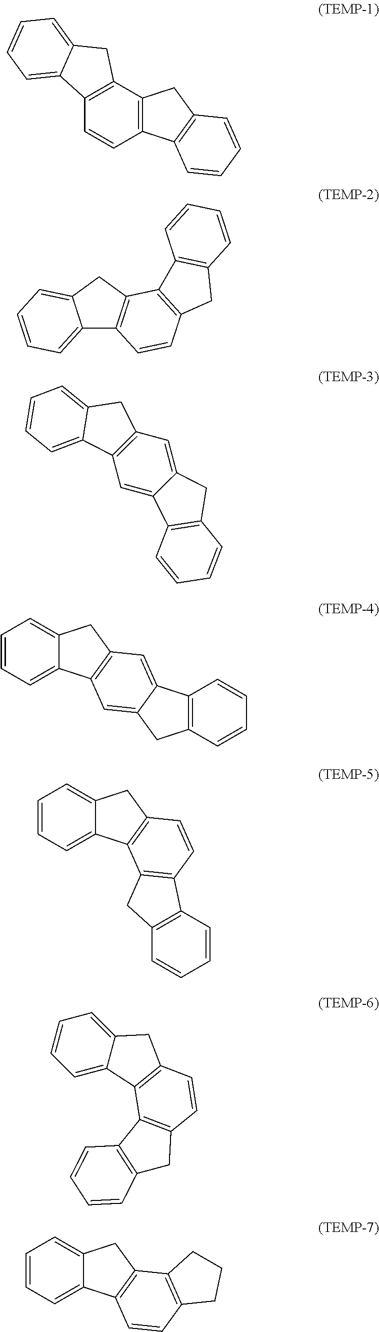

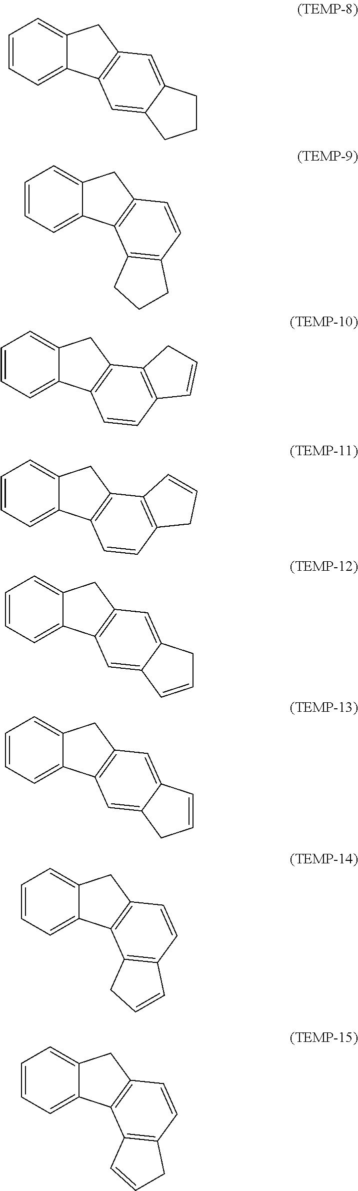

### Substituted Aryl Group (Specific Example Group G1B)

an o-tolyl group,

a m-tolyl group,

a p-tolyl group,

a p-xylyl group,

a m-xylyl group,

an o-xylyl group,

a p-isopropylphenyl group,

a m-isopropylphenyl group,

an o-isopropylphenyl group,

a p-t-butylphenyl group,

a m-t-butylphenyl group,

an o-t-butylphenyl group,

a 3,4,5-trimethylphenyl group,

a 9,9-dimethylfluorenyl group,

a 9,9-diphenylfluorenyl group,

a 9,9-bis(4-methylphenyl)fluorenyl group,

a 9,9-bis(4-isopropylphenyl)fluorenyl group,

a 9,9-bis(4-t-butylphenyl)fluorenyl group,

a cyanophenyl group,

a triphenylsilylphenyl group,

a trimethylsilylphenyl group,

a phenylnaphthyl group,

a naphthylphenyl group, and

a group in which one or more hydrogen atoms of a monovalent group derived from the ring structures represented by any of the general formulas (TEMP-1) to (TEMP-15) are substituted by a substituent.

### Substituted or Unsubstituted Heterocyclic Group

The “heterocyclic group” described in this specification is a ring group having at least one hetero atom in the ring atom. Specific examples of the hetero atom include a nitrogen atom, an oxygen atom, a sulfur atom, a silicon atom, a phosphorus atom, and a boron atom.

The “heterocyclic group” in this specification is a monocyclic group or a fused ring group.

The “heterocyclic group” in this specification is an aromatic heterocyclic group or a non-aromatic heterocyclic group.

Specific examples of the “substituted or unsubstituted heterocyclic group” (specific example group G2) described in this specification include the following unsubstituted heterocyclic group (specific example group G2A), the following substituted heterocyclic group (specific example group G2B), and the like. (Here, the unsubstituted heterocyclic group refers to the case where the “substituted or unsubstituted heterocyclic group” is a “heterocyclic group unsubstituted by a substituent”, and the substituted heterocyclic group refers to the case where the “substituted or unsubstituted heterocyclic group” is a “heterocyclic group substituted by a substituent”.). In this specification, in the case where simply referred as a “heterocyclic group”, it includes both the “unsubstituted heterocyclic group” and the “substituted heterocyclic group.”

The “substituted heterocyclic group” means a group in which one or more hydrogen atom of the “unsubstituted heterocyclic group” are substituted by a substituent. Specific examples of the “substituted heterocyclic group” include a group in which a hydrogen atom of “unsubstituted heterocyclic group” of the following specific example group G2A is substituted by a substituent, the substituted heterocyclic groups of the following specific example group G2B, and the like. It should be noted that the examples of the “unsubstituted heterocyclic group” and the examples of the “substituted heterocyclic group” enumerated in this specification are mere examples, and the “substituted heterocyclic group” described in this specification includes groups in which hydrogen atom bonded with a ring atom of the heterocyclic group itself in the “substituted heterocyclic group” of the specific example group G2B is further substituted by a substituent, and a group in which hydrogen atom of a substituent in the “substituted heterocyclic group” of the specific example group G2B is further substituted by a substituent.

Specific example group G2A includes, for example, the following unsubstituted heterocyclic group containing a nitrogen atom (specific example group G2A1), the following unsubstituted heterocyclic group containing an oxygen atom (specific example group G2A2), the following unsubstituted heterocyclic group containing a sulfur atom (specific example group G2A3), and the monovalent heterocyclic group derived by removing one hydrogen atom from the ring structures represented by any of the following general formulas (TEMP-16) to (TEMP-33) (specific example group G2A4).

Specific example group G2B includes, for example, the following substituted heterocyclic group containing a nitrogen atom (specific example group G2B1), the following substituted heterocyclic group containing an oxygen atom (specific example group G2B2), the following substituted heterocyclic group containing a sulfur atom (specific example group G2B3), and the following group in which one or more hydrogen atoms of the monovalent heterocyclic group derived from the ring structures represented by any of the following general formulas (TEMP-16) to (TEMP-33) are substituted by a substituent (specific example group G2B4).

### Unsubstituted Heterocyclic Group Containing a Nitrogen Atom (Specific Example Group G2A1)

a pyrrolyl group,

an imidazolyl group,

a pyrazolyl group,

a triazolyl group,

a tetrazolyl group,

an oxazolyl group,

an isoxazolyl group,

an oxadiazolyl group,

a thiazolyl group,

an isothiazolyl group,

a thiadiazolyl group,

a pyridyl group,

a pyridazinyl group,

a pyrimidinyl group,

a pyrazinyl group,

a triazinyl group,

an indolyl group,

an isoindolyl group,

an indolizinyl group,

a quinolizinyl group,

a quinolyl group,

an isoquinolyl group,

a cinnolyl group,

a phthalazinyl group,

a quinazolinyl group,

a quinoxalinyl group,

a benzimidazolyl group,

an indazolyl group,

a phenanthrolinyl group,

a phenanthridinyl group,

an acridinyl group,

a phenazinyl group,

a carbazolyl group,

a benzocarbazolyl group,

a morpholino group,

a phenoxazinyl group,

a phenothiazinyl group,

an azacarbazolyl group, and

a diazacarbazolyl group.

### Unsubstituted Heterocyclic Group Containing an Oxygen Atom (Specific Example Group G2A2)

a furyl group,

an oxazolyl group,

an isoxazolyl group,

an oxadiazolyl group,

a xanthenyl group,

a benzofuranyl group,

an isobenzofuranyl group,

a dibenzofuranyl group,

a naphthobenzofuranyl group,

a benzoxazolyl group,

a benzisoxazolyl group,

a phenoxazinyl group,

a morpholino group,

a dinaphthofuranyl group,

an azadibenzofuranyl group,

a diazadibenzofuranyl group,

an azanaphthobenzofuranyl group, and

a diazanaphthobenzofuranyl group.

### Unsubstituted Heterocyclic Group Containing a Sulfur Atom (Specific Example Group G2A3)

a thienyl group,

a thiazolyl group,

an isothiazolyl group,

a thiadiazolyl group,

a benzothiophenyl group (benzothienyl group),

an isobenzothiophenyl group (isobenzothienyl group),

a dibenzothiophenyl group (dibenzothienyl group),

a naphthobenzothiophenyl group (naphthobenzothienyl group),

a benzothiazolyl group,

a benzisothiazolyl group,

a phenothiazinyl group,

a dinaphthothiophenyl group (dinaphthothienyl group),

an azadibenzothiophenyl group (azadibenzothienyl group),

a diazadibenzothiophenyl group (diazadibenzothienyl group),

an azanaphthobenzothiophenyl group (azanaphthobenzothienyl group), and

a diazanaphthobenzothiophenyl group (diazanaphthobenzothienyl group).

### Monovalent Heterocyclic Group Derived by Removing One Hydrogen Atom From the Ring Structures Represented by any of the Following General Formulas (TEMP-16) to (TEMP-33) (Specific Example Group G2A4)

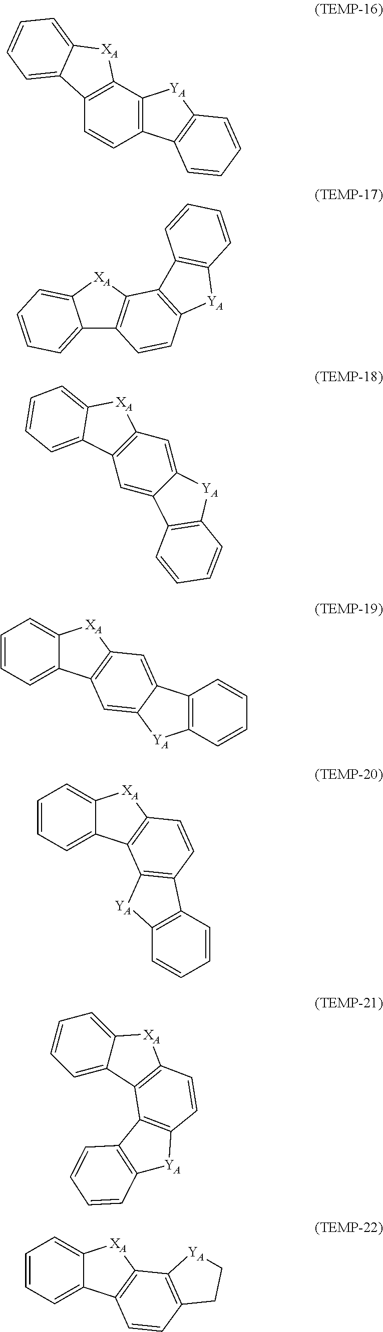

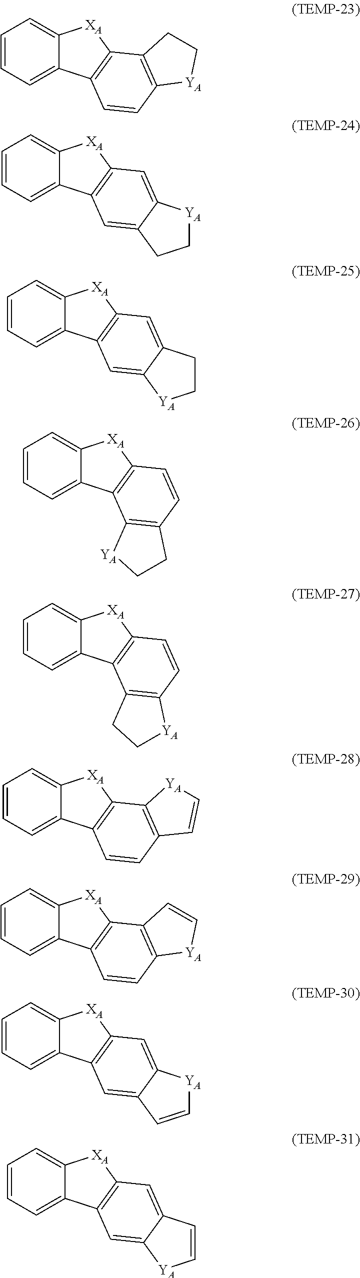

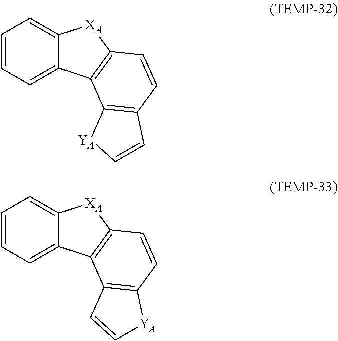

In the general formulas (TEMP-16) to (TEMP-33), X_{A} and Y_{A} are independently an oxygen atom, a sulfur atom, NH, or CH₂. Provided that at least one of X_{A} and Y_{A} is an oxygen atom, a sulfur atom, or NH.

In the general formulas (TEMP-16) to (TEMP-33), when at least one of X_{A} and Y_{A} is NH or CH₂, the monovalent heterocyclic group derived from the ring structures represented by any of the general formulas (TEMP-16) to (TEMP-33) includes a monovalent group derived by removing one hydrogen atom from these NH or CH₂.

### Substituted Heterocyclic Group Containing a Nitrogen Atom (Specific Example Group G2B1)

a (9-phenyl)carbazolyl group,

a (9-biphenylyl)carbazolyl group,

a (9-phenyl)phenylcarbazolyl group,

a (9-naphthyl)carbazolyl group,

a diphenylcarbazol-9-yl group,

a phenylcarbazol-9-yl group,

a methylbenzimidazolyl group,

an ethylbenzimidazolyl group,

a phenyltriazinyl group,

a biphenylyltriazinyl group,

a diphenyltriazinyl group,

a phenylquinazolinyl group, and

a biphenylylquinazolinyl group.

### Substituted Heterocyclic Group Containing an Oxygen Atom (Specific Example Group G2B2)

a phenyldibenzofuranyl group,

a methyldibenzofuranyl group,

a t-butyldibenzofuranyl group, and

a monovalent residue of spiro[9H-xanthene-9,9′-[9H]fluorene].

### Substituted Heterocyclic Group Containing a Sulfur Atom (Specific Example Group G2B3)

a phenyldibenzothiophenyl group,

a methyldibenzothiophenyl group,

a t-butyldibenzothiophenyl group, and

a monovalent residue of spiro[9H-thioxanthene-9,9′-[9H]fluorene].

### Group in Which One or More Hydrogen Atoms of the Monovalent Heterocyclic Group Derived From the Ring Structures Represented by any of the Following General Formulas (TEMP-16) to (TEMP-33) are Substituted by a Substituent (Specific Example Group G2B4)

The “one or more hydrogen atoms of the monovalent heterocyclic group” means one or more hydrogen atoms selected from hydrogen atoms bonded with ring carbon atoms of the monovalent heterocyclic group, a hydrogen atom bonded with a nitrogen atom when at least one of X_{A} and Y_{A} is NH, and hydrogen atoms of a methylene group when one of X_{A} and Y_{A} is CH₂.

### Substituted or Unsubstituted Alkyl Group

Specific examples of the “substituted or unsubstituted alkyl group” (specific example group G3) described in this specification include the following unsubstituted alkyl groups (specific example group G3A) and the following substituted alkyl groups (specific example group G3B). (Here, the unsubstituted alkyl group refers to the case where the “substituted or unsubstituted alkyl group” is an “alkyl group unsubstituted by a substituent”, and the substituted alkyl group refers to the case where the “substituted or unsubstituted alkyl group” is an “alkyl group substituted by a substituent”.). In this specification, in the case where simply referred as an “alkyl group” includes both the “unsubstituted alkyl group” and the “substituted alkyl group.”

The “substituted alkyl group” means a group in which one or more hydrogen atoms in the “unsubstituted alkyl group” are substituted by a substituent. Specific examples of the “substituted alkyl group” include groups in which one or more hydrogen atoms in the following “unsubstituted alkyl group” (specific example group G3A) are substituted by a substituent, the following substituted alkyl group (specific example group G3B), and the like. In this specification, the alkyl group in the “unsubstituted alkyl group” means a linear alkyl group. Thus, the “unsubstituted alkyl group” includes a straight-chain “unsubstituted alkyl group” and a branched-chain “unsubstituted alkyl group”. It should be noted that the examples of the “unsubstituted alkyl group” and the examples of the “substituted alkyl group” enumerated in this specification are mere examples, and the “substituted alkyl group” described in this specification includes a group in which hydrogen atom of the alkyl group itself in the “substituted alkyl group” of the specific example group G3B is further substituted by a substituent, and a group in which hydrogen atom of a substituent in the “substituted alkyl group” of the specific example group G3B is further substituted by a substituent.

### Unsubstituted Alkyl Group (Specific Example Group G3A)

a methyl group,

an ethyl group,

a n-propyl group,

an isopropyl group,

a n-butyl group,

an isobutyl group,

a s-butyl group, and

a t-butyl group.

### Substituted Alkyl Group (Specific Example Group G3B)

a heptafluoropropyl group (including isomers),

a pentafluoroethyl group,

a 2,2,2-trifluoroethyl group, and

a trifluoromethyl group.

### Substituted or Unsubstituted Alkenyl Group

Specific examples of the “substituted or unsubstituted alkenyl group” described in this specification (specific example group G4) include the following unsubstituted alkenyl group (specific example group G4A), the following substituted alkenyl group (specific example group G4B), and the like. (Here, the unsubstituted alkenyl group refers to the case where the “substituted or unsubstituted alkenyl group” is a “alkenyl group unsubstituted by a substituent”, and the “substituted alkenyl group” refers to the case where the “substituted or unsubstituted alkenyl group” is a “alkenyl group substituted by a substituent.”). In this specification, in the case where simply referred as an “alkenyl group” includes both the “unsubstituted alkenyl group” and the “substituted alkenyl group.”

The “substituted alkenyl group” means a group in which one or more hydrogen atoms in the “unsubstituted alkenyl group” are substituted by a substituent. Specific examples of the “substituted alkenyl group” include a group in which the following “unsubstituted alkenyl group” (specific example group G4A) has a substituent, the following substituted alkenyl group (specific example group G4B), and the like. It should be noted that the examples of the “unsubstituted alkenyl group” and the examples of the “substituted alkenyl group” enumerated in this specification are mere examples, and the “substituted alkenyl group” described in this specification includes a group in which a hydrogen atom of the alkenyl group itself in the “substituted alkenyl group” of the specific example group G4B is further substituted by a substituent, and a group in which a hydrogen atom of a substituent in the “substituted alkenyl group” of the specific example group G4B is further substituted by a substituent.

### Unsubstituted Alkenyl Group (Specific Example Group G4A)

a vinyl group,

an allyl group,

a 1-butenyl group,

a 2-butenyl group, and

a 3-butenyl group.

### Substituted Alkenyl Group (Specific Example Group G4B)

a 1,3-butanedienyl group,

a 1-methylvinyl group,

a 1-methylallyl group,

a 1,1-dimethylallyl group,

a 2-methylally group, and

a 1,2-dimethylallylgroup.

### Substituted or Unsubstituted Alkynyl Group

Specific examples of the “substituted or unsubstituted alkynyl group” described in this specification (specific example group G5) include the following unsubstituted alkynyl group (specific example group G5A) and the like. (Here, the unsubstituted alkynyl group refers to the case where the “substituted or unsubstituted alkynyl group” is an “alkynyl group unsubstituted by a substituent”.). In this specification, in the case where simply referred as an “alkynyl group” includes both the “unsubstituted alkynyl group” and the “substituted alkynyl group.”

The “substituted alkynyl group” means a group in which one or more hydrogen atoms in the “unsubstituted alkynyl group” are substituted by a substituent. Specific examples of the “substituted alkynyl group” include a group in which one or more hydrogen atoms in the following “unsubstituted alkynyl group” (specific example group G5A) are substituted by a substituent, and the like.

### Unsubstituted Alkynyl Group (Specific Example Group G5A)

an ethynyl group.

### Substituted or Unsubstituted Cycloalkyl Group

Specific examples of the “substituted or unsubstituted cycloalkyl group” described in this specification (specific example group G6) include the following unsubstituted cycloalkyl group (specific example group G6A), the following substituted cycloalkyl group (specific example group G6B), and the like. (Here, the unsubstituted cycloalkyl group refers to the case where the “substituted or unsubstituted cycloalkyl group” is a “cycloalkyl group unsubstituted by a substituent”, and the substituted cycloalkyl group refers to the case where the “substituted or unsubstituted cycloalkyl group” is a “cycloalkyl group substituted by a substituent”.). In this specification, in the case where simply referred as a “cycloalkyl group” includes both the “unsubstituted cycloalkyl group” and the “substituted cycloalkyl group.”

The “substituted cycloalkyl group” means a group in which one or more hydrogen atoms in the “unsubstituted cycloalkyl group” are substituted by a substituent. Specific examples of the “substituted cycloalkyl group” include a group in which one or more hydrogen atoms in the following “unsubstituted cycloalkyl group” (specific example group G6A) are substituted by a substituent, and examples of the following substituted cycloalkyl group (specific example group G6B), and the like. It should be noted that the examples of the “unsubstituted cycloalkyl group” and the examples of the “substituted cycloalkyl group” enumerated in this specification are mere examples, and the “substituted cycloalkyl group” in this specification includes a group in which one or more hydrogen atoms bonded with the carbon atom of the cycloalkyl group itself in the “substituted cycloalkyl group ” of the specific example group G6B are substituted by a substituent, and a group in which a hydrogen atom of a substituent in the “substituted cycloalkyl group” of specific example group G6B is further substituted by a substituent.

### Unsubstituted Cycloalkyl Group (Specific Example Group G6A)

a cyclopropyl group,

a cyclobutyl group,

a cyclopentyl group,

a cyclohexyl group,

a 1-adamantyl group,

a 2-adamantyl group,

a 1-norbomyl group, and

a 2-norbomyl group.

### Substituted Cycloalkyl Group (Specific Example Group G6B)

a 4-methylcyclohexyl group.

### Group Represented by —Si (R₉₀₁)(R₉₀₂)(R₉₀₃)

Specific examples of the group represented by —Si(R₉₀₁)(R₉₀₂)(R₉₀₃) described in this specification (specific example group G7) include:

—Si(G1)(G1)(G1),

—Si(G1)(G2)(G2),

—Si(G1)(G1)(G2),

—Si(G2)(G2)(G2),

—Si(G3)(G3)(G3), and

—Si(G6)(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —Si(G1)(G1)(G1) are the same or different. Plural G2's in —Si(G1)(G2)(G2) are the same or different. Plural G1's in —Si(G1)(G1)(G2) are the same or different. Plural G2's in —Si(G2)(G2)(G2) are be the same or different. Plural G3's in —Si(G3)(G3)(G3) are the same or different. Plural G6's in —Si(G6)(G6)(G6) are be the same or different.

### Group Represented by —O—(R₉₀₄)

Specific examples of the group represented by —O—(R₉₀₄) in this specification (specific example group G8) include:

—O(G1),

—O(G2),

—O(G3), and

—O(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

### Group Represented by —S—(R₉₀₅)

Specific examples of the group represented by —S—(R₉₀₅) in this specification (specific example group G9) include:

—S(G1),

—S(G2),

—S(G3), and

—S(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

### Group Represented by —N(R₉₀₆)(R₉₀₇)

Specific examples of the group represented by —N(R₉₀₆)(R₉₀₇) in this specification (specific example group G10) include:

—N(G1)(G1),

—N(G2)(G2),

—N(G1)(G2),

—N(G3)(G3), and

—N(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —N(G1)(G1) are the same or different.

Plural G2's in —N(G2)(G2) are the same or different.

Plural G3's in —N(G3)(G3) are the same or different.

Plural G6's in —N(G6)(G6) are the same or different.

### Halogen Atom

Specific examples of the “halogen atom” described in this specification (specific example group G11) include a fluorine atom, a chlorine atom, a bromine atom, an iodine atom, and the like.

### Substituted or Unsubstituted Fluoroalkyl Group

The “substituted or unsubstituted fluoroalkyl group” described in this specification is a group in which at least one hydrogen atom bonded with a carbon atom constituting the alkyl group in the “substituted or unsubstituted alkyl group” is substituted by a fluorine atom, and includes a group in which all hydrogen atoms bonded with a carbon atom constituting the alkyl group in the “substituted or unsubstituted alkyl group” are substituted by a fluorine atom (a perfluoro group). The number of carbon atoms of the “unsubstituted fluoroalkyl group” is 1 to 50, preferably 1 to 30, more preferably 1 to 18, unless otherwise specified in this specification. The “substituted fluoroalkyl group” means a group in which one or more hydrogen atoms of the “fluoroalkyl group” are substituted by a substituent. The “substituted fluoroalkyl group” described in this specification also includes a group in which one or more hydrogen atoms bonded with a carbon atom of the alkyl chains in the “substituted fluoroalkyl group” are further substituted by a substituent, and a group in which one or more hydrogen atom of a substituent in the “substituted fluoroalkyl group” are further substituted by a substituent. Specific examples of the “unsubstituted fluoroalkyl group” include a group in which one or more hydrogen atoms in the “alkyl group” (specific group G3) are substituted by a fluorine atom, and the like.

### Substituted or Unsubstituted Haloalkyl Group

The “substituted or unsubstituted haloalkyl group” described in this specification is a group in which at least one hydrogen atom bonded with a carbon atom constituting the alkyl group in the “substituted or unsubstituted alkyl group” is substituted by a halogen atom, and also includes a group in which all hydrogen atoms bonded with a carbon atom constituting the alkyl group in the “substituted or unsubstituted alkyl group” are substituted by a halogen atom. The number of carbon atoms of the “unsubstituted haloalkyl group” is 1 to 50, preferably 1 to 30, more preferably 1 to 18, unless otherwise specified in this specification. The “substituted haloalkyl group” means a group in which one or more hydrogen atoms of the “haloalkyl group” are substituted by a substituent. The “substituted haloalkyl group” described in this specification also includes a group in which one or more hydrogen atoms bonded with a carbon atom of the alkyl chain in the “substituted haloalkyl group” are further substituted by a substituent, and a group in which one or more hydrogen atoms of a substituent in the “substituted haloalkyl group” are further substituted by a substituent. Specific examples of the “unsubstituted haloalkyl group” include a group in which one or more hydrogen atoms in the “alkyl group” (specific example group G3) are substituted by a halogen atom, and the like. A haloalkyl group is sometimes referred to as an alkyl halide group.

### Substituted or Unsubstituted Alkoxy Group

Specific examples of the “substituted or unsubstituted alkoxy group” described in this specification include a group represented by —O(G3), wherein G3 is the “substituted or unsubstituted alkyl group” described in the specific example group G3. The number of carbon atoms of the “unsubstituted alkoxy group” is 1 to 50, preferably 1 to 30, more preferably 1 to 18, unless otherwise specified in this specification.

### Substituted or Unsubstituted Alkylthio Group

Specific examples of the “substituted or unsubstituted alkylthio group” described in this specification include a group represented by —S(G3), wherein G3 is the “substituted or unsubstituted alkyl group” described in the specific example group G3. The number of carbon atoms of the “unsubstituted alkylthio group” is 1 to 50, preferably 1 to 30, more preferably 1 to 18, unless otherwise specified in this specification.

### Substituted or Unsubstituted Aryloxy Group

Specific examples of the “substituted or unsubstituted aryloxy group” described in this specification include a group represented by —O(G1), wherein G1 is the “substituted or unsubstituted aryl group” described in the specific example group G1. The number of ring carbon atoms of the “unsubstituted aryloxy group” is 6 to 50, preferably 6 to 30, more preferably 6 to 18, unless otherwise specified in this specification.

### Substituted or Unsubstituted Arylthio Group

Specific examples of the “substituted or unsubstituted arylthio group” described in this specification include a group represented by —S(G1), wherein G1 is a “substituted or unsubstituted aryl group” described in the specific example group G1. The number of ring carbon atoms of the “unsubstituted arylthio group” is 6 to 50, preferably 6 to 30, more preferably 6 to 18, unless otherwise specified in this specification.

### Substituted or Unsubstituted Trialkylsilyl Group

Specific examples of the “trialkylsilyl group” described in this specification include a group represented by —Si(G3)(G3)(G3), where G3 is the “substituted or unsubstituted alkyl group” described in the specific example group G3. Plural G3's in —Si(G3)(G3)(G3) are the same or different. The number of carbon atoms in each alkyl group of the “trialkylsilyl group” is 1 to 50, preferably 1 to 20, more preferably 1 to 6, unless otherwise specified in this specification.

### Substituted or Unsubstituted Aralkyl Group

Specific examples of the “substituted or unsubstituted aralkyl group” described in this specification is a group represented by -(G3)-(G1), wherein G3 is the “substituted or unsubstituted alkyl group” described in the specific example group G3, and G1 is the “substituted or unsubstituted aryl group” described in the specific example group G1. Therefore, the “aralkyl group” is a group in which a hydrogen atom of the “alkyl group” is substituted by an “aryl group” as a substituent, and is one form of the “substituted alkyl group.” The “unsubstituted aralkyl group” is the “unsubstituted alkyl group” substituted by the “unsubstituted aryl group”, and the number of carbon atoms of the “unsubstituted aralkyl group” is 7 to 50, preferably 7 to 30, more preferably 7 to 18, unless otherwise specified in this specification.

Specific examples of the “substituted or unsubstituted aralkyl group” include a benzyl group, a 1-phenylethyl group, a 2-phenylethyl group, a 1-phenylisopropyl group, a 2-phenylisopropyl group, a phenyl-t-butyl group, an α-naphthylmethyl group, a 1-α-naphthylethyl group, a 2-α-naphthylethyl group, a 1-α-naphthylisopropyl group, a 2-α-naphthylisopropyl group, a β-naphthylmethyl group, a 1-β-naphthylethyl group, a 2-β-naphthylethyl group, a 1-β-naphthylisopropyl group, a 2-β-naphthylisopropyl group, and the like.

Unless otherwise specified in this specification, examples of the substituted or unsubstituted aryl group described in this specification preferably include a phenyl group, a p-biphenyl group, a m-biphenyl group, an o-biphenyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-terphenyl-4-yl group, an o-terphenyl-3-yl group, an o-terphenyl-2-yl group, a 1-naphthyl group, a 2-naphthyl group, an anthryl group, a phenanthryl group, a pyrenyl group, a chrysenyl group, a triphenylenyl group, a fluorenyl group, a 9,9′-spirobifluorenyl group, 9,9-dimethylfluorenyl group, 9,9-diphenylfluorenyl group, and the like.

Unless otherwise specified in this specification, examples of the substituted or unsubstituted heterocyclic groups described in this specification preferably include a pyridyl group, a pyrimidinyl group, a triazinyl group, a quinolyl group, an isoquinolyl group, a quinazolinyl group, a benzimidazolyl group, a phenanthrolinyl group, a carbazolyl group (a 1-carbazolyl group, a 2-carbazolyl group, a 3-carbazolyl group, a 4-carbazolyl group, or a 9-carbazolyl group), a benzocarbazolyl group, an azacarbazolyl group, a diazacarbazolyl group, a dibenzofuranyl group, a naphthobenzofuranyl group, an azadibenzofuranyl group, a diazadibenzofuranyl group, a dibenzothiophenyl group, a naphthobenzothiophenyl group, an azadibenzothiophenyl group, a diazadibenzothiophenyl group, a (9-phenyl)carbazolyl group (a (9-phenyl)carbazol-1-yl group, a (9-phenyl)carbazol-2-yl group, a (9-phenyl)carbazol-3-yl group, or a (9-phenyl)carbazol-4-yl group), a (9-biphenylyl)carbazolyl group, a (9-phenyl)phenylcarbazolyl group, a diphenylcarbazol-9-yl group, a phenylcarbazol-9-yl group, a phenyltriazinyl group, a biphenylyltriazinyl group, a diphenyltriazinyl group, a phenyldibenzofuranyl group, a phenyldibenzothiophenyl group, and the like.

In this specification, the carbazolyl group is specifically any of the following groups, unless otherwise specified in this specification.

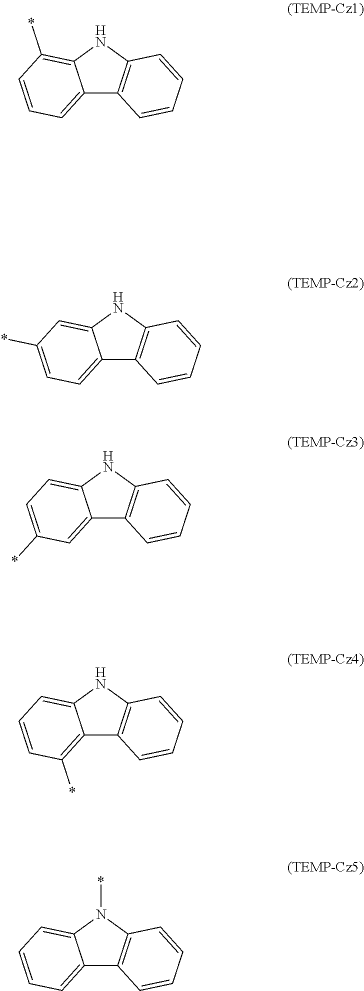 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

In this specification, the (9-phenyl)carbazolyl group is specifically any of the following groups, unless otherwise specified in this specification.

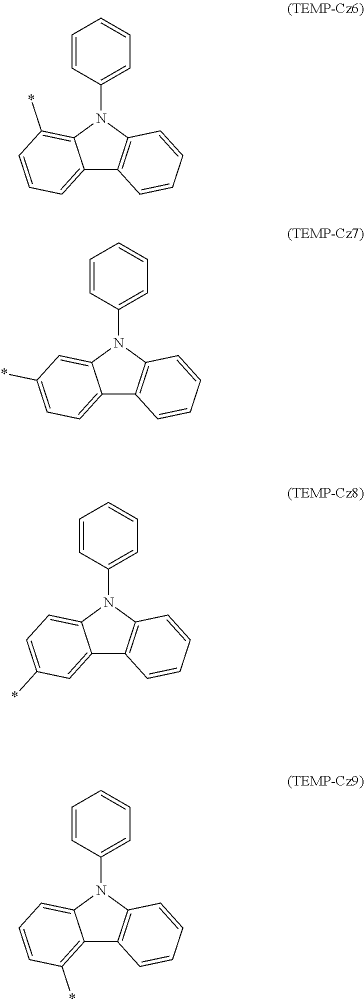 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

In the general formulas (TEMP-Cz1) to (TEMP-Cz9), * represents a bonding position.

In this specification, the dibenzofuranyl group and the dibenzothiophenyl group are specifically any of the following groups, unless otherwise specified in this specification.

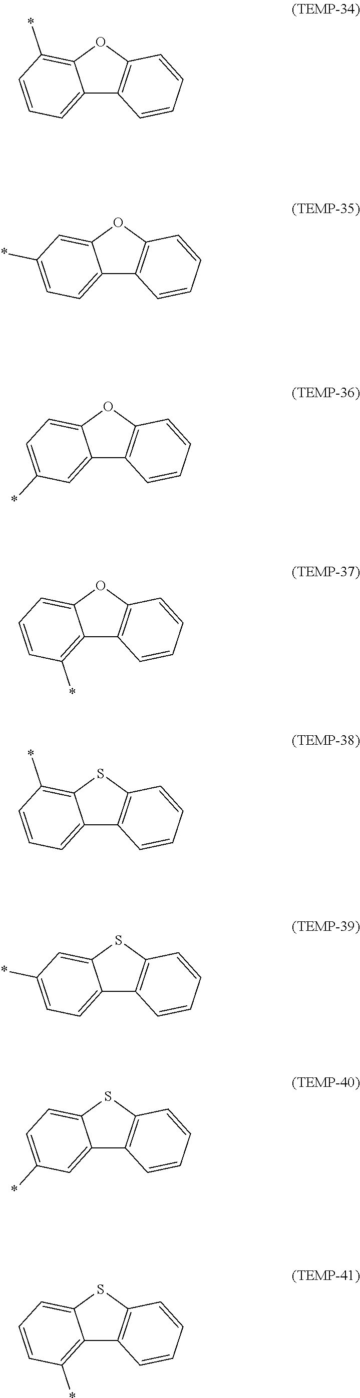

In the general formulas (TEMP-34) to (TEMP-41), * represents a bonding position.

The substituted or unsubstituted alkyl group described in this specification is preferably a methyl group, an ethyl group, a propyl group, an isopropyl group, a n-butyl group, an isobutyl group, a t-butyl group, or the like, unless otherwise specified in this specification.

### Substituted or Unsubstituted Arylene Group

The “substituted or unsubstituted arylene group” described in this specification is a divalent group derived by removing one hydrogen atom on the aryl ring of the “substituted or unsubstituted aryl group”, unless otherwise specified. Specific examples of the “substituted or unsubstituted arylene group” (specific example group G12) include a divalent group derived by removing one hydrogen atom on the aryl ring of the “substituted or unsubstituted aryl group” described in the specific example group G1, and the like.

### Substituted or Unsubstituted Divalent Heterocyclic Group

The “substituted or unsubstituted divalent heterocyclic group” described in this specification is a divalent group derived by removing one hydrogen atom on the heterocyclic ring of the “substituted or unsubstituted heterocyclic group”, unless otherwise specified. Specific examples of the “substituted or unsubstituted divalent heterocyclic group” (specific example group G13) include a divalent group derived by removing one hydrogen atom on the heterocyclic ring of the “substituted or unsubstituted heterocyclic group” described in the specific example group G2, and the like.

### Substituted or Unsubstituted Alkylene Group

The “substituted or unsubstituted alkylene group” described in this specification is a divalent group derived by removing one hydrogen atom on the alkyl chain of the “substituted or unsubstituted alkyl group”, unless otherwise specified. Specific examples of the “substituted or unsubstituted alkylene group” (specific example group G14) include a divalent group derived by removing one hydrogen atom on the alkyl chain of the “substituted or unsubstituted alkyl group” described in the specific example group G3, and the like.

The substituted or unsubstituted arylene group described in this specification is preferably any group of the following general formulas (TEMP-42) to (TEMP-68), unless otherwise specified in this specification.

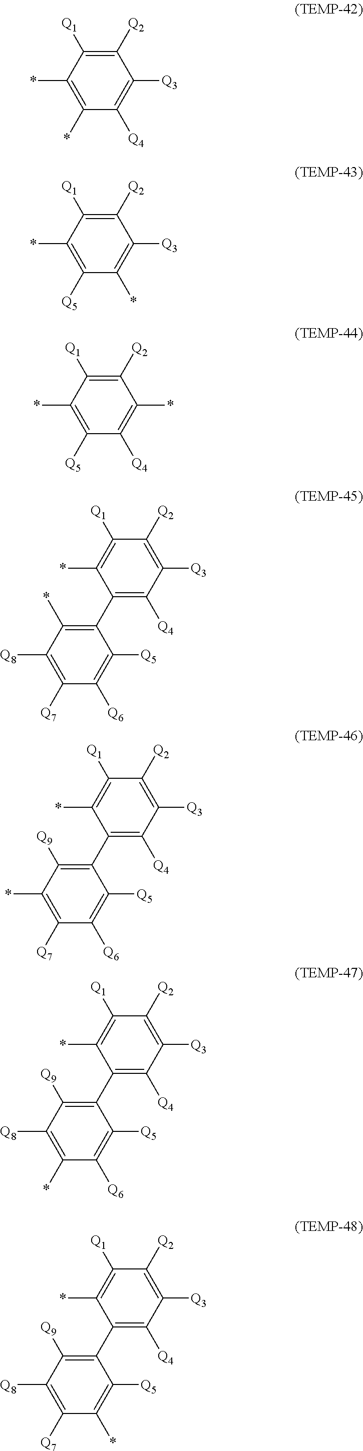

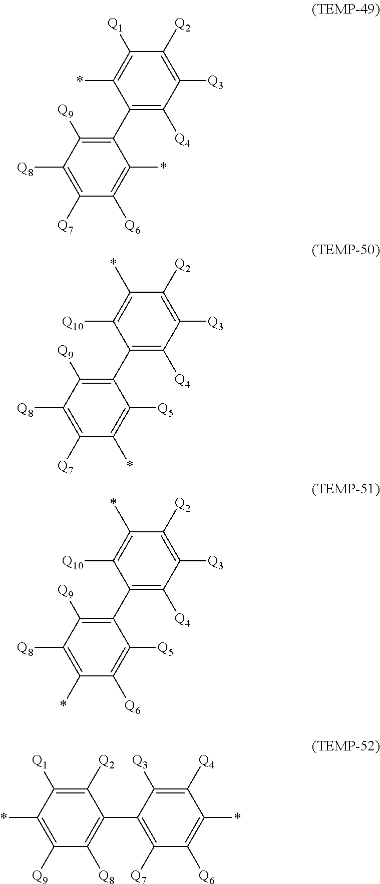

In the general formulas (TEMP-42) to (TEMP-52), Q₁ to Q₁₀ are independently a hydrogen atom or a substituent.

In the general formulas (TEMP-42) to (TEMP-52), * represents a bonding position.

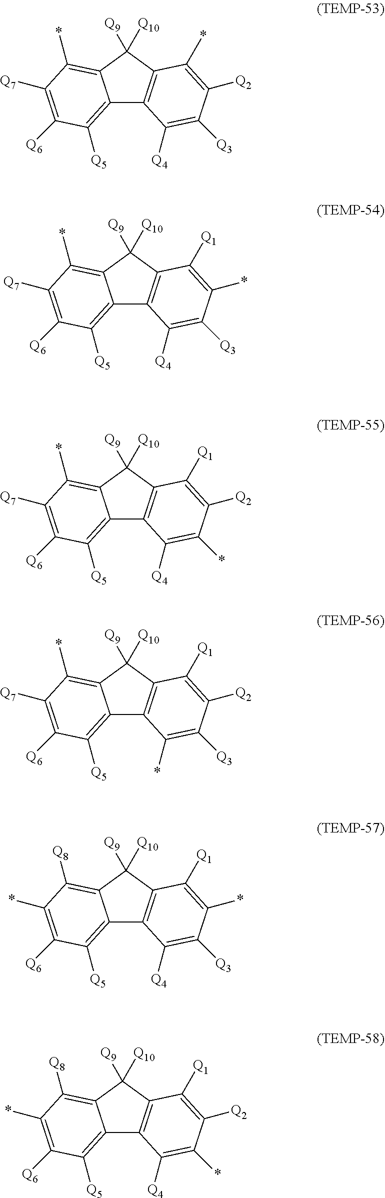

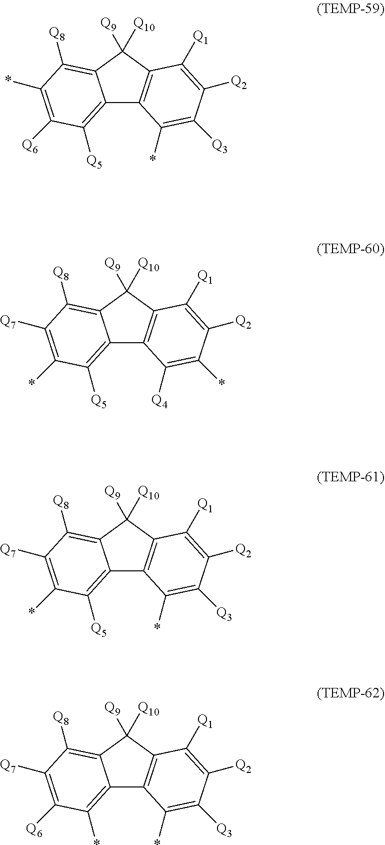

In the general formulas (TEMP-53) to (TEMP-62), Q₁ to Q₁₀ are independently a hydrogen atom or a substituent.

Q₉ and Q₁₀ may be bonded with each other via a single bond to form a ring.

In the general formulas (TEMP-53) to (TEMP-62), * represents a bonding position.

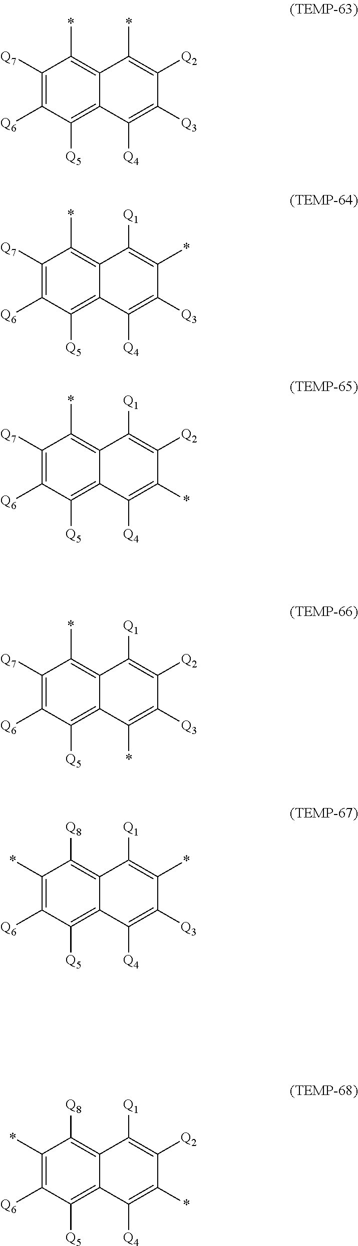

In the general formulas (TEMP-63) to (TEMP-68), Q₁ to Q₈ are independently a hydrogen atom or a substituent.

In the general formulas (TEMP-63) to (TEMP-68), * represents a bonding position. The substituted or unsubstituted divalent heterocyclic group described in this specification is preferably any group of the following general formulas (TEMP-69) to (TEMP-102), unless otherwise specified in this specification.

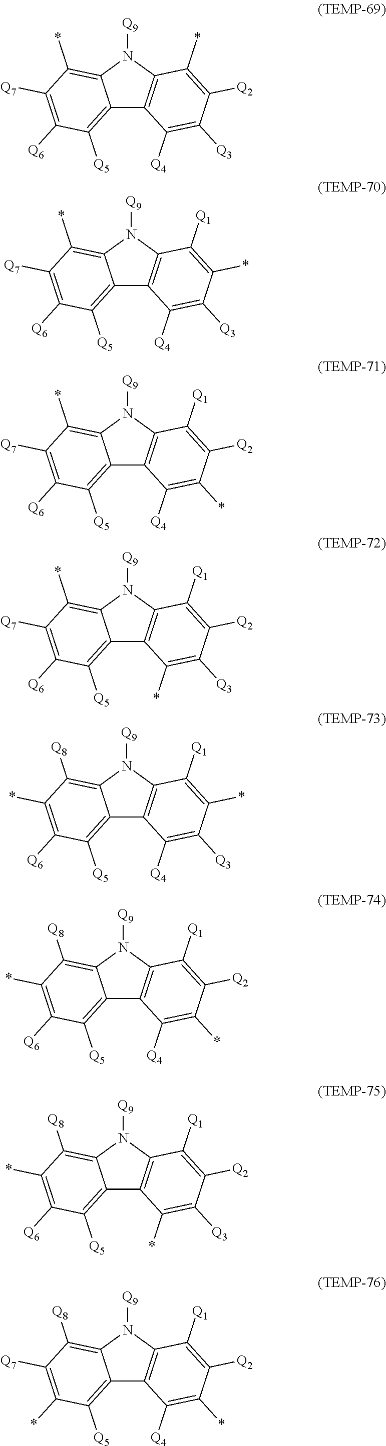

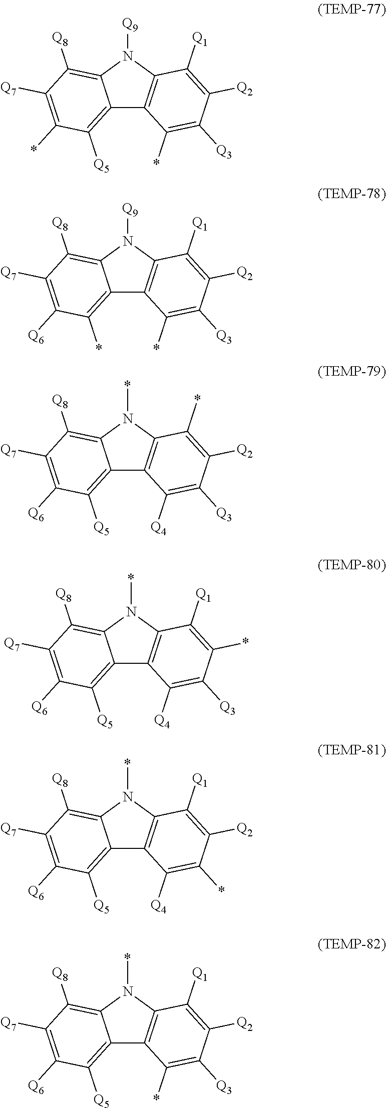

In the general formulas (TEMP-69) to (TEMP-82), Q₁ to Q₉ are independently a hydrogen atom or a substituent.

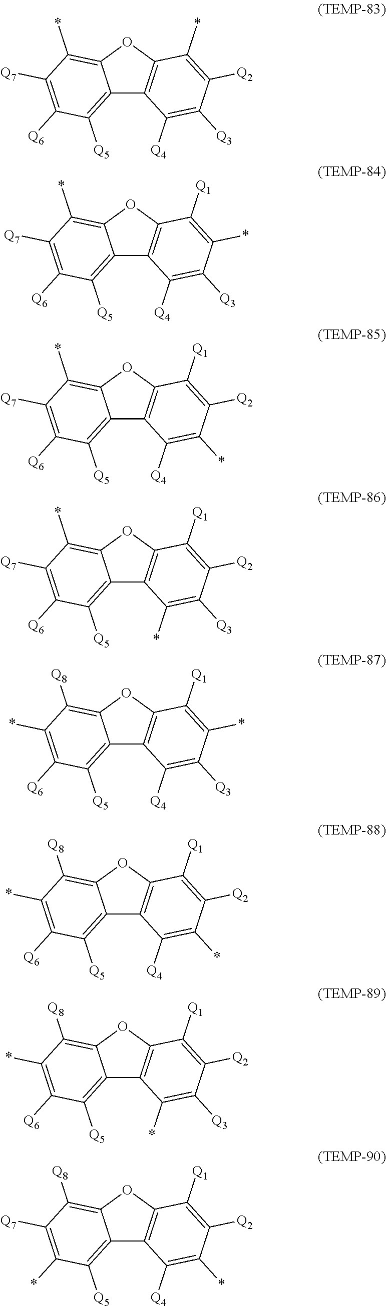

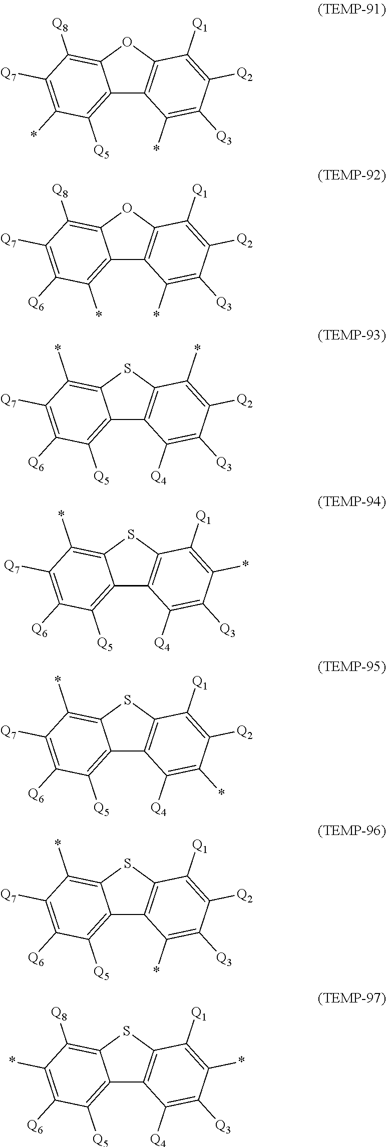

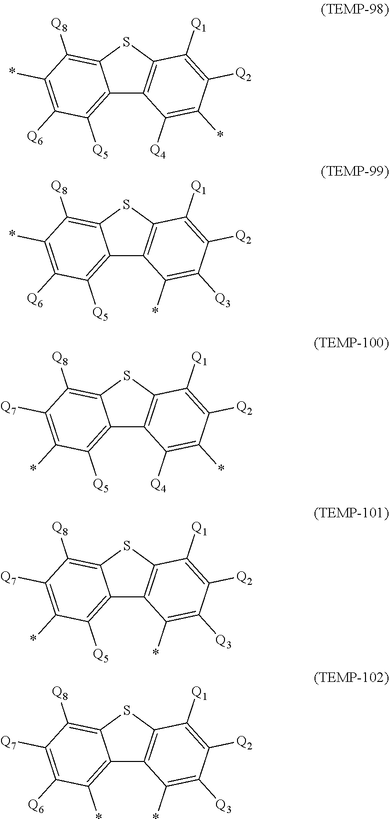

In the general formulas (TEMP-83) to (TEMP-102), Q₁ to Q₈ are independently a hydrogen atom or a substituent.

The above is the explanation of the “Substituent described in this specification.”

### The Case Where Bonded With Each Other to Form a Ring

In this specification, the case where “one or more sets of adjacent two or more form a substituted or unsubstituted monocycle by bonding with each other, form a substituted or unsubstituted fused ring by bonding with each other, or do not bond with each other” means the case where “one or more sets of adjacent two or more form a substituted or unsubstituted monocycle by bonding with each other”; the case where “one or more sets of adjacent two or more form a substituted or unsubstituted fused ring by bonding with each other”; and the case where “one or more sets of adjacent two or more do not bond with each other.”

The case where “one or more sets of adjacent two or more form a substituted or unsubstituted monocycle by bonding with each other” and the case where “one or more sets of adjacent two or more form a substituted or unsubstituted fused ring by bonding with each other” in this specification (these cases may be collectively referred to as “the case where forming a ring by bonding with each other”) will be described below. The case of an anthracene compound represented by the following general formula (TEMP-103) in which the mother skeleton is an anthracene ring will be described as an example.

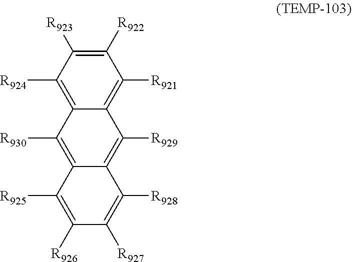

For example, in the case where “one or more sets of adjacent two or more among R₉₂₁ to R₉₃₀ form a ring by bonding with each other”, the one set of adjacent two includes a pair of R₉₂₁ and R₉₂₂, a pair of R₉₂₂ and R₉₂₃, a pair of R₉₂₃ and R₉₂₄, a pair of R₉₂₄ and R₉₃₀, a pair of R₉₃₀ and R₉₂₅, a pair of R₉₂₅ and R₉₂₆, a pair of R₉₂₆ and R₉₂₇, a pair of R₉₂₇ and R₉₂₈, a pair of R₉₂₈ and R₉₂₉, and a pair of R₉₂₉ and R₉₂₁.

The “one or more sets” means that two or more sets of the adjacent two or more sets may form a ring at the same time. For example, R₉₂₁ and R₉₂₂ form a ring Q_{A} by bonding with each other, and at the same, time R₉₂₅ and R₉₂₆ form a ring Q_{B} by bonding with each other, the anthracene compound represented by the general formula (TEMP-103) is represented by the following general formula (TEMP-104).

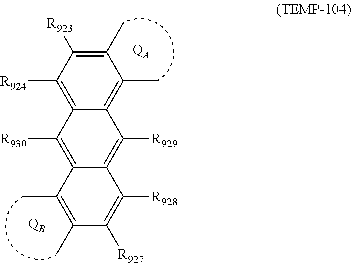

The case where the “set of adjacent two or more” form a ring includes not only the case where the set (pair) of adjacent “two” is bonded with as in the above-mentioned examples, but also the case where the set of adjacent “three or more” are bonded with each other. For example, it means the case where R₉₂₁ and R₉₂₂ form a ring Q_{A} by bonding with each other, and R₉₂₂ and R₉₂₃ form a ring Q_{C} by bonding with each other, and adjacent three (R₉₂₁, R₉₂₂ and R₉₂₃) form rings by bonding with each other and together fused to the anthracene mother skeleton. In this case, the anthracene compound represented by the general formula (TEMP-103) is represented by the following general formula (TEMP-105). In the following general formula (TEMP-105), the ring Q_{A} and the ring Q_{C} share R₉₂₂.

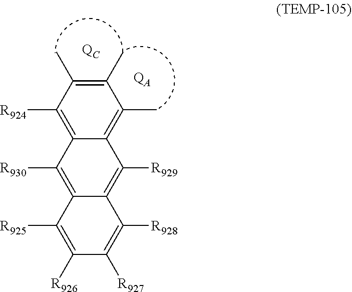

The “monocycle” or “fused ring” formed may be a saturated ring or an unsaturated ring, as a structure of the formed ring alone. Even when the “one pair of adjacent two” forms a “monocycle” or a “fused ring”, the “monocycle” or the “fused ring” may form a saturated ring or an unsaturated ring. For example, the ring Q_{A} and the ring Q_{B} formed in the general formula (TEMP-104) are independently a “monocycle” or a “fused ring.” The ring Q_{A} and the ring Q_{C} formed in the general formula (TEMP-105) are “fused ring.” The ring Q_{A} and ring Q_{C} of the general formula (TEMP-105) are fused ring by fusing the ring Q_{A} and the ring Q_{C} together. When the ring Q_{A} of the general formula (TEMP-104) is a benzene ring, the ring Q_{A} is a monocycle. When the ring Q_{A} of the general formula (TEMP-104) is a naphthalene ring, the ring Q_{A} is a fused ring.

The “unsaturated ring” means an aromatic hydrocarbon ring or an aromatic heterocyclic ring. The “saturated ring” means an aliphatic hydrocarbon ring, or a non-aromatic heterocyclic ring.

Specific examples of the aromatic hydrocarbon ring include a structure in which the group listed as a specific example in the specific example group G1 is terminated by a hydrogen atom.

Specific examples of the aromatic heterocyclic ring include a structure in which the aromatic heterocyclic group listed as a specific example in the example group G2 is terminated by a hydrogen atom.

Specific examples of the aliphatic hydrocarbon ring include a structure in which the group listed as a specific example in the specific example group G6 is terminated by a hydrogen atom.

The term “to form a ring” means forming a ring only with plural atoms of the mother skeleton, or with plural atoms of the mother skeleton and one or more arbitrary elements in addition. For example, the ring Q_{A} shown in the general formula (TEMP-104), which is formed by bonding R₉₂₁ and R₉₂₂ with each other, is a ring formed from the carbon atom of the anthracene skeleton with which R₉₂₁ is bonded, the carbon atom of the anthracene skeleton with which R₉₂₂ is bonded, and one or more arbitrary elements. For example, in the case where the ring Q_{A} is formed with R₉₂₁ and R₉₂₂, when a monocyclic unsaturated ring is formed with the carbon atom of the anthracene skeleton with which R₉₂₁ is bonded, the carbon atom of the anthracene skeleton with which R₉₂₂ is bonded, and four carbon atoms, the ring formed with R₉₂₁ and R₉₂₂ is a benzene ring.

Here, the “arbitrary element” is preferably at least one element selected from the group consisting of a carbon element, a nitrogen element, an oxygen element, and a sulfur element, unless otherwise specified in this specification. In the arbitrary element (for example, a carbon element or a nitrogen element), a bond which does not form a ring may be terminated with a hydrogen atom or the like, or may be substituted with “arbitrary substituent” described below. When an arbitrary element other than a carbon element is contained, the ring formed is a heterocyclic ring.

The number of “one or more arbitrary element(s)” constituting a monocycle or a fused ring is preferably 2 or more and 15 or less, more preferably 3 or more and 12 or less, and still more preferably 3 or more and 5 or less, unless otherwise specified in this specification.

The “monocycle” is preferable among the “monocycle” and the “fused ring”, unless otherwise specified in this specification.

The “unsaturated ring” is preferable among the “saturated ring” and the “unsaturated ring”, unless otherwise specified in this specification.

Unless otherwise specified in this specification, the “monocycle ” is preferably a benzene ring.

Unless otherwise specified in this specification, the “unsaturated ring” is preferably a benzene ring.

Unless otherwise specified in this specification, when “one or more sets of adjacent two or more” are “bonded with each other to form a substituted or unsubstituted monocycle” or “bonded with each other to form a substituted or unsubstituted fused ring”, this specification, one or more sets of adjacent two or more are preferably bonded with each other to form a substituted or unsubstituted “unsaturated ring” from plural atoms of the mother skeleton and one or more and 15 or less elements which is at least one kind selected from a carbon elements, a nitrogen element, an oxygen element, and a sulfur element.

The substituent in the case where the above-mentioned “monocycle” or “fused ring” has a substituent is, for example, an “arbitrary substituent” described below. Specific examples of the substituent which the above-mentioned “monocycle” or “fused ring” has include the substituent described above in the “Substituent described in this specification” section.

The substituent in the case where the above-mentioned “saturated ring” or “unsaturated ring” has a substituent is, for example, an “arbitrary substituent” described below. Specific examples of the substituent which the above-mentioned “monocycle” or “fused ring” has include the substituent described above in the “Substituent described in this specification” section.

The foregoing describes the case where “one or more sets of adjacent two or more form a substituted or unsubstituted monocycle by bonding with each other” and the case where “one or more sets of adjacent two or more form a substituted or unsubstituted fused ring by bonding with each other ” (the case where “forming a ring by bonding with each other”).

### Substituent in the Case of “Substituted or Unsubstituted”

In one embodiment in this specification, the substituent (in this specification, sometimes referred to as an “arbitrary substituent”) in the case of “substituted or unsubstituted” is, for example, a group selected from the group consisting of:

an unsubstituted alkyl group including 1 to 50 carbon atoms,

an unsubstituted alkenyl group including 2 to 50 carbon atoms,

an unsubstituted alkynyl group including 2 to 50 carbon atoms,

an unsubstituted cycloalkyl group including 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇),

a halogen atom, a cyano group, a nitro group,

an unsubstituted aryl group including 6 to 50 ring carbon atoms, and

an unsubstituted heterocyclic group including 5 to 50 ring atoms,

wherein, R₉₀₁ to R₉₀₇ are independently

a hydrogen atom,

a substituted or unsubstituted alkyl group including 1 to 50 carbon atoms,

a substituted or unsubstituted cycloalkyl group including 3 to 50 ring carbon atoms,

a substituted or unsubstituted aryl group including 6 to 50 ring carbon atoms, or

a substituted or unsubstituted heterocyclic group including 5 to 50 ring atoms.

When two or more R₉₀₁'s are present, the two or more R₉₀₁'s may be the same or different.

When two or more R₉₀₂'s are present, the two or more R₉₀₂'s may be the same or different.

When two or more R₉₀₃'s are present, the two or more R₉₀₃'s may be the same or different.

When two or more R₉₀₄'s are present, the two or more R₉₀₄'s may be the same or different.

When two or more R₉₀₅'s are present, the two or more R₉₀₅'s may be the same or different.

When two or more R₉₀₆'s are present, the two or more R₉₀₆'s may be the same or different.

When two or more R₉₀₇'s are present, the two or more R₉₀₇'s may be the same or different.

In one embodiment, the substituent in the case of “substituted or unsubstituted” is a group selected from the group consisting of:

an alkyl group including 1 to 50 carbon atoms,

an aryl group including 6 to 50 ring carbon atoms, and

a heterocyclic group including 5 to 50 ring atoms.

In one embodiment, the substituent in the case of “substituted or unsubstituted” is a group selected from the group consisting of:

an alkyl group including 1 to 18 carbon atoms,

an aryl group including 6 to 18 ring carbon atoms, and

a heterocyclic group including 5 to 18 ring atoms.

Specific examples of each of the arbitrary substituents include specific examples of substituent described in the section “Substituent described in this specification” above.

Unless otherwise specified in this specification, adjacent arbitrary substituents may form a “saturated ring” or an “unsaturated ring”, preferably form a substituted or unsubstituted saturated 5-membered ring, a substituted or unsubstituted saturated 6-membered ring, a substituted or unsubstituted unsaturated 5-membered ring, or a substituted or unsubstituted unsaturated 6-membered ring, more preferably form a benzene ring.

Unless otherwise specified in this specification, the arbitrary substituent may further have a substituent. The substituent which the arbitrary substituent further has is the same as that of the above-mentioned arbitrary substituent.

In this specification, the numerical range represented by “AA to BB” means the range including the numerical value AA described on the front side of “AA to BB” as the lower limit and the numerical value BB described on the rear side of “AA to BB” as the upper limit.

### Organic Electroluminescence Device

The organic EL device according to an aspect of the invention is

an organic electroluminescence device having a cathode, an anode, and an organic layer disposed between the cathode and the anode, wherein

the organic layer includes an emitting layer and a first layer,

the first layer is disposed between the anode and the emitting layer, and

the first layer contains a first hole-transporting material represented by the formula (1) described below and a second hole-transporting material represented by the formula (11) described below.

Each of the first hole-transporting material and the second hole-transporting material contained in the first layer may be one kinds alone or two or more kinds thereof.

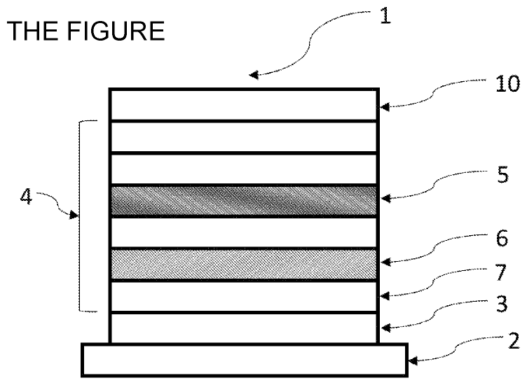

Schematic configuration of an organic EL device will be explained with reference to FIG. 1.

The organic EL device 1 has a substrate 2, an anode 3, a cathode 10, and an organic layer 4 disposed between the anode 3 and the cathode 10, and the organic layer 4 includes an emitting layer 5. The organic EL device further has a first layer 6 (hole-transporting layer) disposed between the anode 3 and the emitting layer 5. In one embodiment, it may further have a hole-injecting layer 7 disposed between the anode 3 and the first layer 6 (hole-transporting layer). Also, it may have an electron-injecting layer and an electron-transporting layer (not shown in the FIGURE) formed between the emitting layer 5 and the cathode 10. It may further have an electron-blocking layer (not shown in the FIGURE) provided on the anode 3 side of the emitting layer 5, and a hole-blocking layer (not shown in the FIGURE) provided on the cathode 10 side of the emitting layer 5. By employing such a configuration, electrons or holes are confined in the emitting layer 5, whereby efficiency of formation of excitons in the emitting layer 5 can be further enhanced.

### First Hole-Transporting Material

Next, the first hole-transporting material used in the first layer of the organic EL device of an aspect of the invention is a compound represented by the following formula (1):

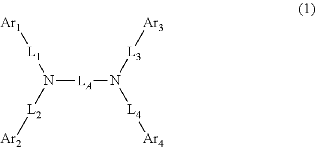

In the formula (1),

L_{A} is
a substituted or unsubstituted arylene group including 6 to 50 ring carbon atoms, or
a substituted or unsubstituted divalent heterocyclic group including 5 to 50 ring atoms;

L₁ to L₄ are independently a single bond or a linking group;

when each of L₁ to L₄ is a linking group, the linking group is
a substituted or unsubstituted arylene group including 6 to 50 ring carbon atoms, or
a substituted or unsubstituted divalent heterocyclic group including 5 to 50 ring atoms;

Ar₁ to Ar₄ are independently
a substituted or unsubstituted aryl group including 6 to 50 ring carbon atoms, or
a substituted or unsubstituted monovalent heterocyclic group including 5 to 50 ring atoms.

In one embodiment, in the formula (1), when each of Li to La which is a linking group having a substituent, and when each of Ar₁ to Ar₄ have a substituent, the substituent is not —N(R_{906A})(R_{907A}), where R_{906A} and R_{907A} are independently a substituted or unsubstituted aryl group including 6 to 50 ring carbon atoms, or a substituted or unsubstituted monovalent heterocyclic group including 5 to 50 ring atoms.

In one embodiment, L_{A} in the formula (1) is a substituted or unsubstituted arylene group including 6 to 50 ring carbon atoms.

In one embodiment, L_{A} in the formula (1) is a substituted or unsubstituted arylene group including 6 to 30 ring carbon atoms.

In one embodiment, L_{A} in the formula (1) is a group selected from the group consisting of
a substituted or unsubstituted phenylene group,
a substituted or unsubstituted biphenylene group,
a substituted or unsubstituted terphenylene group,
a substituted or unsubstituted quaterphenylene group, and
a substituted or unsubstituted naphthylene group.

In one embodiment, L_{A} in the formula (1) is a group selected from the group consisting of
an unsubstituted phenylene group,
an unsubstituted biphenylene group,
an unsubstituted terphenylene group,
an unsubstituted quaterphenylene group, and
an unsubstituted naphthylene group.

In one embodiment, the compound represented by the formula (1) is a compound represented by the following formula (1-1):

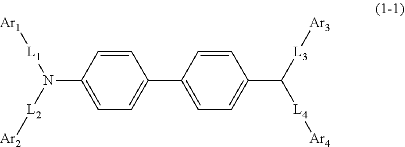

In the formula (1-1), L₁ to L₄ and Ar₁ to Ar₄ are as defined in the formula (1).

In one embodiment, Ar₁ to Ar₄ in each of the formula (1) and the formula (1-1) are independently a substituted or unsubstituted aryl group including 6 to 50 ring carbon atoms.

In one embodiment, Ar₁ to Ar₄ in each of the formula (1) and the formula (1-1) are independently a substituted or unsubstituted aryl group including 6 to 30 ring carbon atoms.

In one embodiment, Ar₁ to Ar₄ in each of the formula (1) and the formula (1-1) are independently a group selected from the group consisting of
a substituted or unsubstituted phenyl group,
a substituted or unsubstituted biphenyl group,
a substituted or unsubstituted terphenyl group,
a substituted or unsubstituted quarterphenyl group,
a substituted or unsubstituted naphthyl group,
a substituted or unsubstituted fluorenyl group,
a substituted or unsubstituted anthryl group,
a substituted or unsubstituted 9,9′-spirobifluorenyl group,
a substituted or unsubstituted benzofluorenyl group,
a substituted or unsubstituted phenanthryl group, and
a substituted or unsubstituted benzophenanthryl group.

In one embodiment, Ar₁ to Ar₄ in each of the formula (1) and the formula (1-1) are independently a group selected from the group consisting of
an unsubstituted phenyl group,
an unsubstituted biphenyl group,
an unsubstituted terphenyl group,
an unsubstituted quarterphenyl group,
an unsubstituted naphthyl group,
an unsubstituted fluorenyl group,
an unsubstituted anthryl group,
an unsubstituted 9,9′-spirobifluorenyl group,
an unsubstituted benzofluorenyl group,
an unsubstituted phenanthryl group, and
an unsubstituted benzophenanthryl group.

In one embodiment, L₁ to L₄ in the formula (1) are independently a single bond, or a substituted or unsubstituted arylene group including 6 to 50 ring carbon atoms.

In one embodiment, L₁ to L₄ in the formula (1) are independently a single bond, or a substituted or unsubstituted arylene group including 6 to 20 ring carbon atoms.

In one embodiment, L₁ to L₄ in the formula (1) are independently a single bond, or an unsubstituted arylene group including 6 to 20 ring carbon atoms.

In one embodiment, L₁ to L₄ in the formula (1) are independently a single bond, or a group selected from the group consisting of
an unsubstituted phenyl group,
a substituted or unsubstituted phenylene group,
a substituted or unsubstituted biphenylene group,
a substituted or unsubstituted fluorenylene group,
a substituted or unsubstituted terphenylene group,
a substituted or unsubstituted quaterphenylene group,
a substituted or unsubstituted naphthylene group, and
a substituted or unsubstituted anthrylene group.

In one embodiment, the substituent in the case of “substituted or unsubstituted” in the formula (1) is selected from
a substituted or unsubstituted alkyl group including 1 to 50 carbon atoms, and
a substituted or unsubstituted aryl group including 6 to 50 ring carbon atoms.

Specific examples of the compound represented by the formula (1) will be described below, but these are merely examples, and the compound represented by the formula (1) is not limited to the following specific examples.

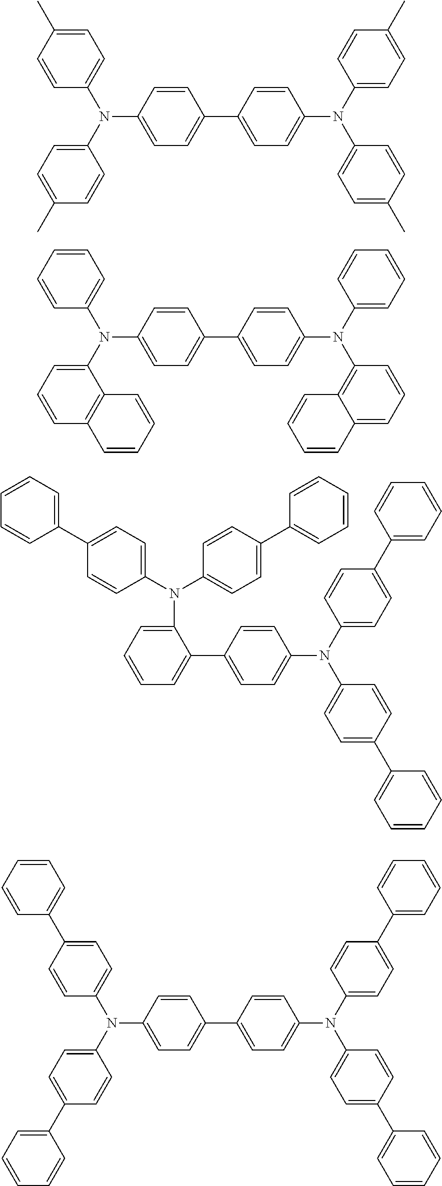

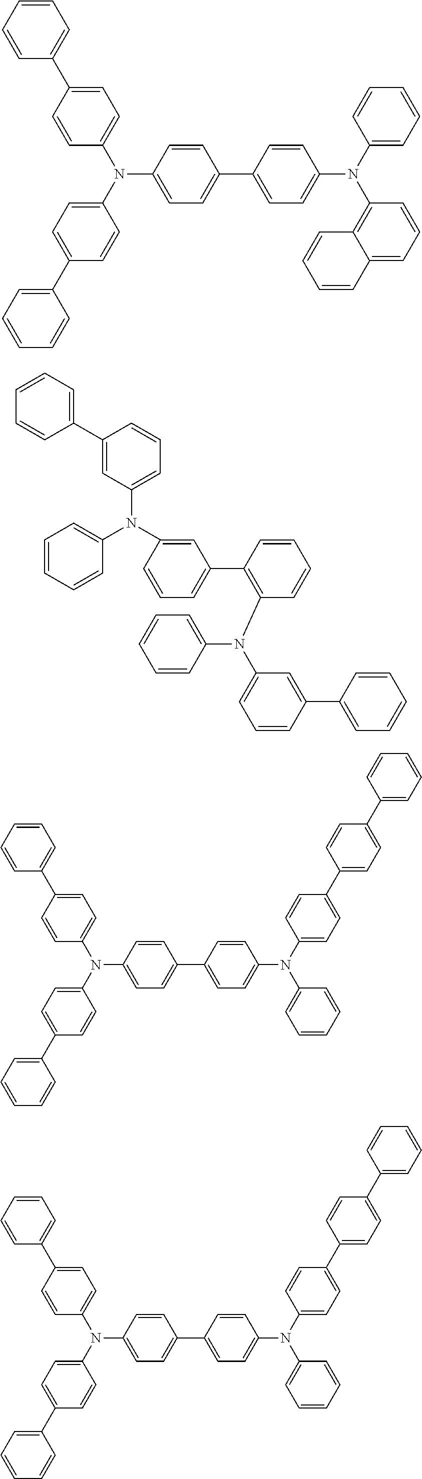

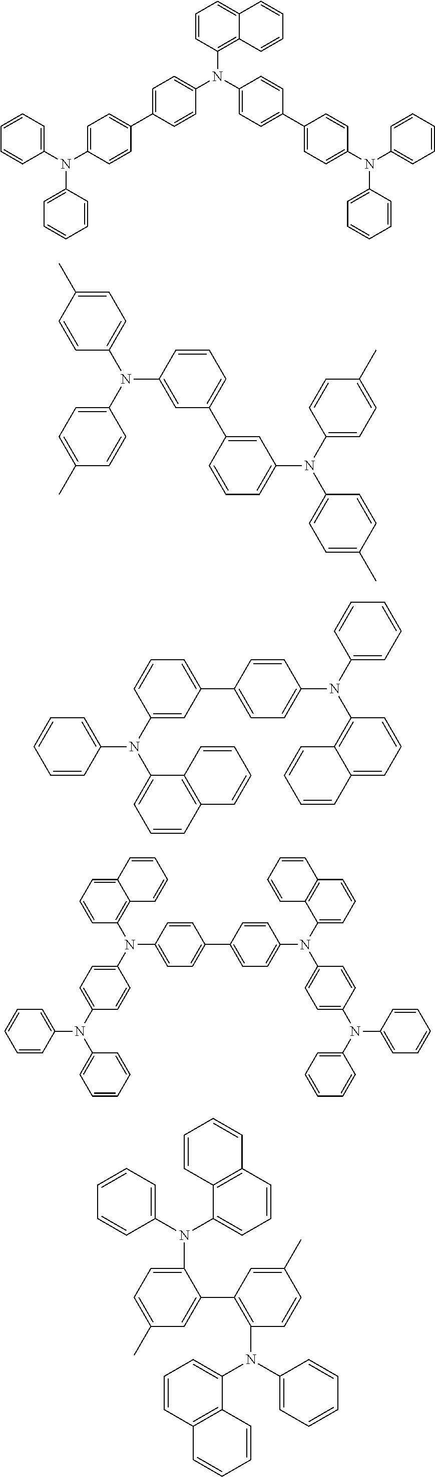

### Second Hole-Transporting Material

Next, the second hole-transporting material used in the first layer of the organic EL device of an aspect of the invention is a compound represented by the following formula (11):

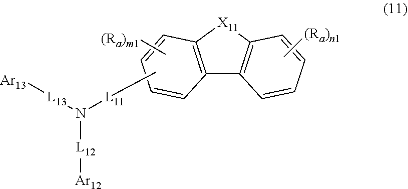

In the formula (11),

L₁₁ to L₁₃ are independently a single bond or a linking group;

when each of L₁₁ to L₁₃ is a linking group, the linking group is
a substituted or unsubstituted arylene group including 6 to 50 ring carbon atoms, or
a substituted or unsubstituted divalent heterocyclic group including 5 to 50 ring atoms;

each set of L₁₁ and L₁₂, L₁₁ and L₁₃, L₁₁ and Ar₁₂, and L₁₁ and Ar₁₃ does not form a heterocycle containing N by bonding with each other;

Ar₁₂ and Ar₁₃ are independently
a substituted or unsubstituted aryl group including 6 to 50 ring carbon atoms, or
a substituted or unsubstituted monovalent heterocyclic group including 5 to 50 ring atoms;

X₁₁ is O, S, or C(R₁₁)(R₁₂);

R₁₁ and R₁₂ form a substituted or unsubstituted, saturated or unsaturated ring by bonding with each other, or do not form the ring;

R₁₁ and R₁₂ which do not form the ring are independently a hydrogen atom,
a substituted or unsubstituted aryl group including 6 to 50 ring carbon atoms, or
a substituted or unsubstituted monovalent heterocyclic group including 5 to 60 ring atoms;

one or more sets of adjacent two or more Rₐ's form a substituted or unsubstituted, saturated or unsaturated ring by bonding with each other, or do not form the ring;

Rₐ which does not form the ring is
a substituted or unsubstituted alkyl group including 1 to 50 carbon atoms,
a substituted or unsubstituted aryl group including 6 to 50 ring carbon atoms, or
a substituted or unsubstituted monovalent heterocyclic group including 5 to 50 ring atoms;

m1 is an integer of 0 to 3; when m1 is 2 or more, two or more Rₐ's are the same as or different from each other;

n1 is an integer of 0 to 4; and when n1 is 2 or more, two or more Rₐ's are the same as or different from each other.

In one embodiment, the compound represented by the formula (11) is a compound selected from the group consisting of a compound represented by the following formula (11-1), a compound represented by the following formula (11-2), a compound represented by the following formula (11-3), and a compound represented by the following formula (11-4):

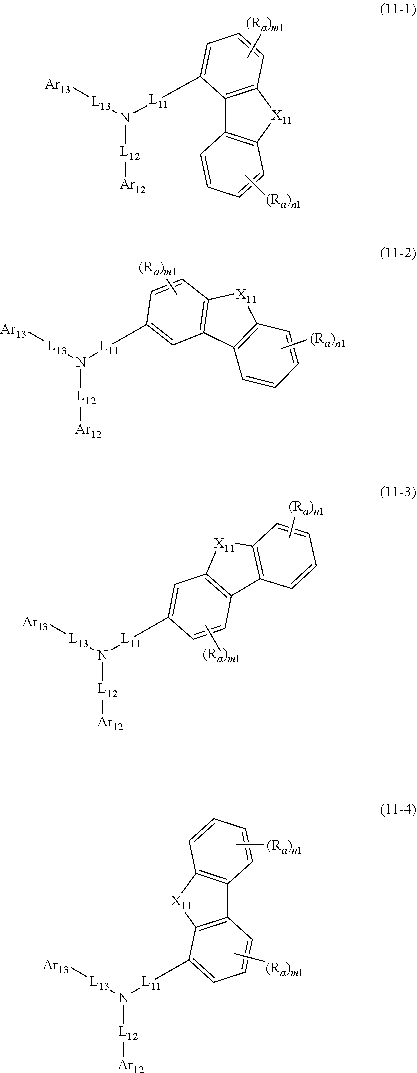

In the formulas (11-1) to (11-4), L₁₁ to L₁₃, Ar₁₂, Ar₁₃, X₁₁, Rₐ, m1, and n1 are as defined in the formula (11).

In one embodiment, the compound represented by the formula (11) is a compound represented by the following formula (11-1A) or (11-4A):

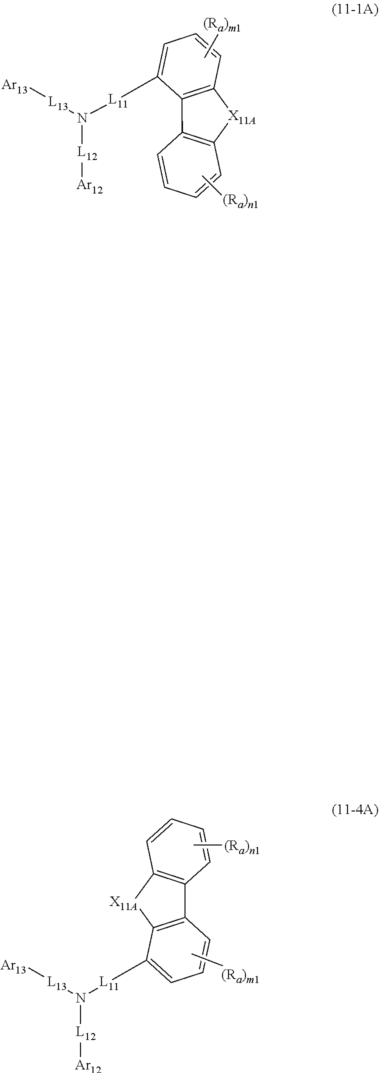

In the formulas (11-1A) and (11-4A), L₁₁ to L₁₃, Ar₁₂, Ar₁₃, Rₐ, m1, and n1 are as defined in the formula (11); and

X_{11A} is O or S.

In one embodiment, the compound represented by the formula (11) is a compound represented by the following formula (11-1B) or (11-3B):

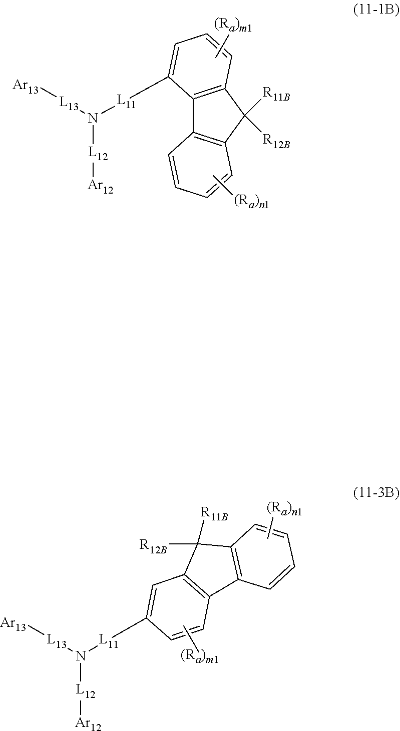

In the formulas (11-1B) and (11-3B), L₁₁ to L₁₃, Ar₁₂, Ar₁₃, Rₐ, m1, and n1 are as defined in the formula (11);

R_{11B} and R_{12B} form a substituted or unsubstituted, saturated or unsaturated ring by bonding with each other, or do not form the ring; and

R_{11B} and R_{12B} which do not form the ring are independently a substituted or unsubstituted aryl group including 6 to 50 ring carbon atoms.

In one embodiment, L₁₁ to L₁₃ in the formula (11) are independently a single bond, or a substituted or unsubstituted arylene group including 6 to 50 ring carbon atoms.

In one embodiment, L₁₁ to L₁₃ in the formula (11) are independently a single bond, or a group selected from the group consisting of
a substituted or unsubstituted phenylene group,
a substituted or unsubstituted biphenylene group,
a substituted or unsubstituted terphenylene group,
a substituted or unsubstituted quaterphenylene group, and
a substituted or unsubstituted naphthylene group.

In one embodiment, L₁₁ to L₁₃ in the formula (11) are independently a single bond, or a group selected from the group consisting of
an unsubstituted phenylene group,
an unsubstituted biphenylene group,
an unsubstituted terphenylene group,
an unsubstituted quaterphenylene group, and
an unsubstituted naphthylene group.

In one embodiment, L₁₁ to L₁₃ in the formula (11) are independently a single bond, or an unsubstituted phenylene group.

In one embodiment, Ar₁₂ and Ar₁₃ in the formula (11) are independently a group selected from the group consisting of
a substituted or unsubstituted phenyl group,
a substituted or unsubstituted naphthyl group,
a substituted or unsubstituted fluorenyl group,
a substituted or unsubstituted 9,9′-spirobifluorenyl group,
a substituted or unsubstituted benzofluorenyl group,
a substituted or unsubstituted phenanthryl group,
a substituted or unsubstituted phenanthryl group,
a substituted or unsubstituted dibenzofuranyl group, and
a substituted or unsubstituted dibenzothiophenyl group.

In one embodiment, Ar₁₂ and Ar₁₃ in the formula (11) are independently a group selected from the group consisting of
an unsubstituted phenyl group,
an unsubstituted naphthyl group,
an unsubstituted fluorenyl group,
an unsubstituted 9,9′-spirobifluorenyl group,
an unsubstituted benzofluorenyl group,
an unsubstituted phenanthryl group,
an unsubstituted benzophenanthryl group,
an unsubstituted dibenzofuranyl group, and
an unsubstituted dibenzothiophenyl group.

In one embodiment, Rₐ in the formula (11) is a substituted or unsubstituted aryl group including 6 to 50 ring carbon atoms.

In one embodiment, Rₐ in the formula (11) is a substituted or unsubstituted aryl group including 6 to 30 ring carbon atoms.

In one embodiment, Rₐ in the formula (11) is a group selected from the group consisting of
a substituted or unsubstituted phenyl group,
a substituted or unsubstituted naphthyl group,
a substituted or unsubstituted biphenyl group,
a substituted or unsubstituted terphenyl group,
a substituted or unsubstituted anthryl group,
a substituted or unsubstituted phenanthryl group, and
a substituted or unsubstituted benzophenanthryl group.

In one embodiment, Rₐ in the formula (11) is a group selected from the group consisting of
an unsubstituted phenyl group,
an unsubstituted naphthyl group,
an unsubstituted biphenyl group,
an unsubstituted terphenyl group,
an unsubstituted anthryl group,
an unsubstituted phenanthryl group, and
an unsubstituted benzophenanthryl group.

In one embodiment, either or both of m1 and n1 in the formula (11) are 0.

In one embodiment, both of m1 and n1 in the formula (11) are 0.

In one embodiment, the substituent in the case of “substituted or unsubstituted” in the formula (11) is selected from
a substituted or unsubstituted alkyl group including 1 to 50 carbon atoms, and
a substituted or unsubstituted aryl group including 6 to 50 ring carbon atoms.

Specific examples of the compound represented by the formula (11) will be described below, but these are merely examples, and the compound represented by the formula (11) is not limited to the following specific examples.

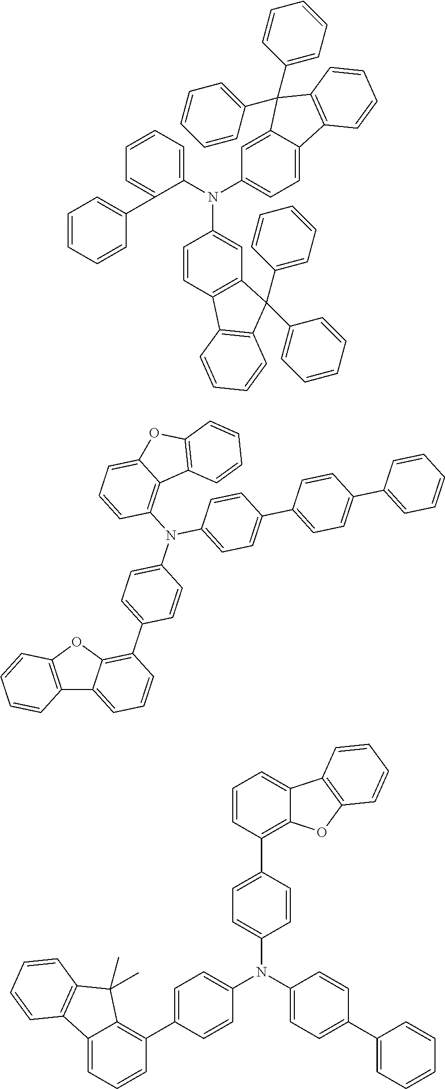

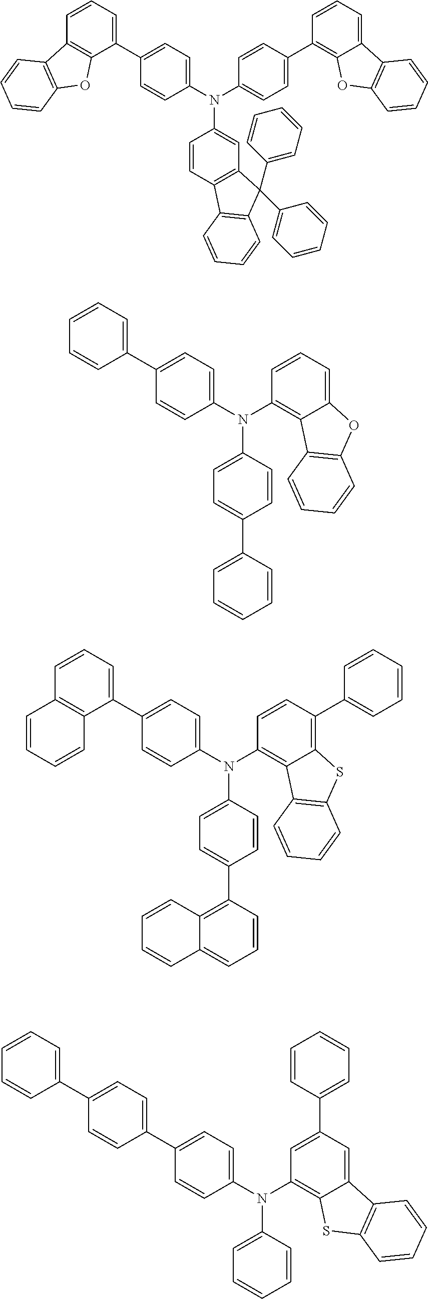 [SMILES: c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1 ; c1ccc(-c2ccc(N(c3ccc(-c4ccccc4)cc3)c3cccc4oc5ccccc5c34)cc2)cc1 ; c1ccc(-c2ccc(N(c3ccc(-c4cccc5ccccc45)cc3)c3ccc(-c4cccc5ccccc45)cc3)c3c2sc2ccccc23)cc1 ; c1ccc(-c2ccc(-c3ccc(N(c4ccccc4)c4cc(-c5ccccc5)cc5c4sc4ccccc45)cc3)cc2)cc1]

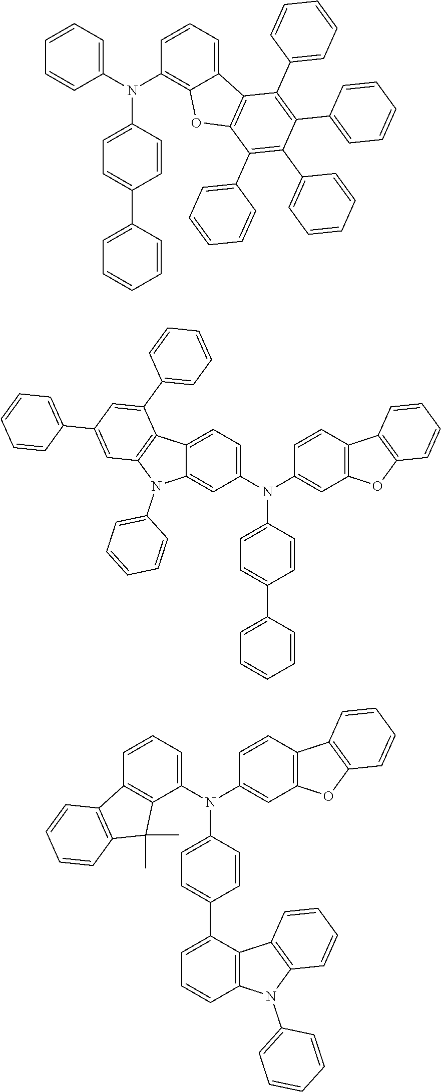 [SMILES: c1ccc(-c2ccc(N(c3ccccc3)c3cccc4c3oc3c(-c5ccccc5)c(-c5ccccc5)c(-c5ccccc5)c(-c5ccccc5)c34)cc2)cc1 ; c1ccc(-c2ccc(N(c3ccc4c(c3)oc3ccccc34)c3ccc4c5c(-c6ccccc6)cc(-c6ccccc6)cc5n(-c5ccccc5)c4c3)cc2)cc1 ; CC1(C)c2ccccc2-c2cccc(N(c3ccc(-c4cccc5c4c4ccccc4n5-c4ccccc4)cc3)c3ccc4c(c3)oc3ccccc34)c21]

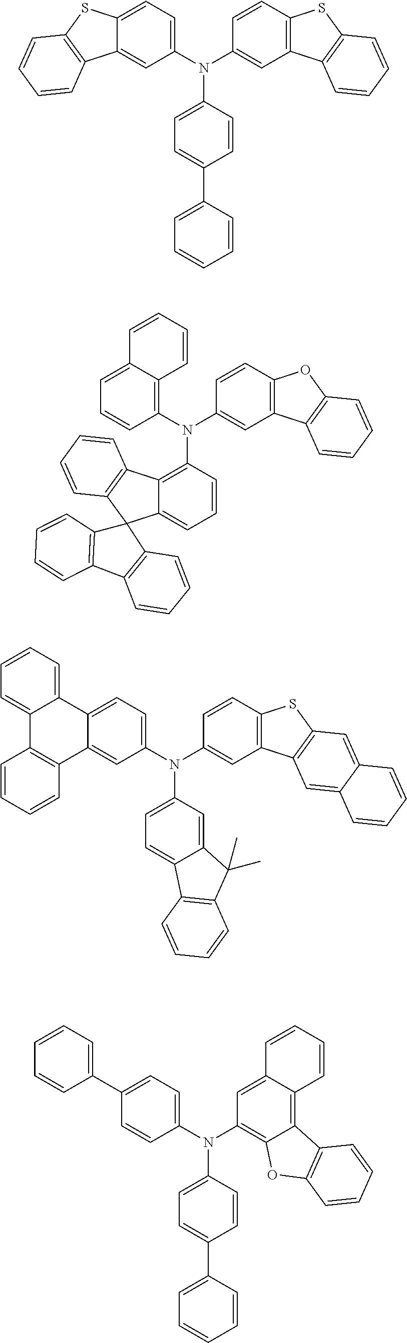 [SMILES: c1ccc(-c2ccc(N(c3ccc4sc5ccccc5c4c3)c3ccc4sc5ccccc5c4c3)cc2)cc1 ; c1ccc2c(c1)-c1ccccc1C21c2ccccc2-c2c(N(c3ccc4oc5ccccc5c4c3)c3cccc4ccccc34)cccc21 ; CC1(C)c2ccccc2-c2ccc(N(c3ccc4sc5cc6ccccc6cc5c4c3)c3ccc4c5ccccc5c5ccccc5c4c3)cc21 ; c1ccc(-c2ccc(N(c3ccc(-c4ccccc4)cc3)c3cc4ccccc4c4c3oc3ccccc34)cc2)cc1]

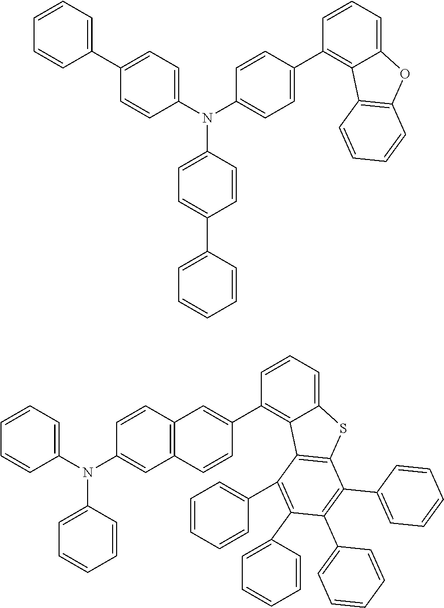 [SMILES: c1ccc(-c2ccc(N(c3ccc(-c4ccccc4)cc3)c3ccc(-c4cccc5oc6ccccc6c45)cc3)cc2)cc1 ; c1ccc(-c2c(-c3ccccc3)c(-c3ccccc3)c3c(sc4cccc(-c5ccc6cc(N(c7ccccc7)c7ccccc7)ccc6c5)c43)c2-c2ccccc2)cc1]

Next, a relationship between the first and second hole-transporting materials contained in the first layer in the organic EL device of an aspect of the invention will be described.

Here, which any of two compounds is the first hole-transporting material or the second hole-transporting material is mainly determined based on the magnitude of the ionization potential. However, it is not uniformly determined only based on the magnitude of the ionization potential, and determined rather depending on the characteristics possessed by the compounds, in some cases. A compound may be the first hole-transporting material or the second hole-transporting material, depending on the other compound combined. In other words, which hole-transporting material among two materials becomes the first hole-transporting material or the second hole-transporting material is relatively determined.

In one embodiment, the first hole-transporting material has an ionization potential value smaller than the ionization potential value of the second hole-transporting material.

The ionization potential is measured by the method described in Examples.

In one embodiment, the mass ratio of the first hole-transporting material to the second hole-transporting material in the first layer is within a range of 80:20 to 20:80.

In one embodiment, the mass ratio of the first hole-transporting material to the second hole-transporting material in the first layer is within a range of 70:30 to 30:70.

In one embodiment, the mass ratio of the first hole-transporting material to the second hole-transporting material in the first layer is around 50:50.

known materials and device configurations may be applied to the organic EL device according to an aspect of the invention, as long as the first layer contains a first hole-transporting material and a second hole-transporting material, wherein the first hole-transporting material is a compound represented by the formula (1), and the second hole-transporting material may be a compound represented by the formula (11), and the effect of the invention is not impaired.

Parts which can be used in the organic EL device according to an aspect of the invention, materials for forming respective layers, other than the above compounds, and the like, will be described below.

### Substrate

A substrate is used as a support of an emitting device. As the substrate, glass, quartz, plastic or the like can be used, for example. In addition, a flexible substrate may be used. The “flexible substrate” means a bendable (flexible) substrate, and specific examples thereof include a plastic substrate formed of polycarbonate, polyvinyl chloride, or the like.

### Anode

For an anode formed on the substrate, metals, alloys, electrically conductive compounds, mixtures thereof, and the like, which have a large work function (specifically 4.0 eV or higher) are preferably used. Specific examples thereof include indium oxide-tin oxide (ITO: Indium Tin Oxide), indium oxide-tin oxide containing silicon or silicon oxide, indium oxide-zinc oxide, tungsten oxide, indium oxide containing zinc oxide, graphene, and the like. In addition, gold (Au), platinum (Pt), a nitride of a metallic material (for example, titanium nitride), and the like may be given.

### Hole-Injecting Layer

The hole-injecting layer is a layer containing a substance having a high hole-injecting property. As such substances having a high hole-injecting property, molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, an aromatic amine compound, or a polymer compound (oligomers, dendrimers, polymers, etc.) can be given.

### Hole-Transporting Layer

The hole-transporting layer is a layer containing a substance having a high hole-transporting property. For the hole-transporting layer, an aromatic amine compound, a carbazole derivative, an anthracene derivative, or the like can be used, in addition to the first and second hole-transporting materials. Polymer compounds such as poly(N-vinylcarbazole) (abbreviation: PVK) and poly(4-vinyltriphenylamine) (abbreviation: PVTPA) can also be used. However, a substance other than the above-described substances may be used as long as the substance has a higher transporting property of holes rather than electrons. It should be noted that the layer containing the substance having a high hole-transporting property may be not only a single layer, but also a stacked layer composed of two or more layers formed of the above-described substances.

### Guest Material for Emitting Layer

The emitting layer is a layer containing a substance having a high emitting property, and can be formed by the use of various materials. For example, as the substances having a high emitting property, a fluorescent compound which emits fluorescence and a phosphorescent compound which emits phosphorescence can be used. The fluorescent compound is a compound which can emit from a singlet excited state, and the phosphorescent compound is a compound which can emit from a triplet excited state.

As a blue fluorescent emitting material which can be used for an emitting layer, pyrene derivatives, styrylamine derivatives, chrysene derivatives, fluoranthene derivatives, fluorene derivatives, diamine derivatives, triarylamine derivatives, and the like can be used. As a green fluorescent emitting material which can be used for an emitting layer, aromatic amine derivatives and the like can be used. As a red fluorescent emitting material which can be used for an emitting layer, tetracene derivatives, diamine derivatives and the like can be used.

As a blue phosphorescent emitting material which can be used for an emitting layer, metal complexes such as iridium complexes, osmium complexes, platinum complexes and the like are used. As a green phosphorescent emitting material which can be used for an emitting layer, iridium complexes and the like are used. As a red phosphorescent emitting material which can be used for an emitting layer, metal complexes such as iridium complexes, platinum complexes, terbium complexes, europium complexes and the like are used.

### Host Material for Emitting Layer

The emitting layer may have a constitution in which the above-mentioned substance having a high emitting property (guest material) is dispersed in the other substance (host material). As the substances which disperse the substance having a high emitting property in the emitting layer, a variety of substances can be used. It is preferable to use a substance having a higher lowest unoccupied orbital level (LUMO level) and a lower highest occupied orbital level (HOMO level) than those of the substance having a high emitting property.

As such materials (host material) for dispersing the substance having a high emitting property, 1) metal complexes such as an aluminum complex, a beryllium complex, and a zinc complex, 2) heterocyclic compounds such as an oxadiazole derivative, a benzimidazole derivative, and a phenanthroline derivative, 3) fused aromatic compounds such as a carbazole derivative, an anthracene derivative, a phenanthrene derivative, a pyrene derivative, and a chrysene derivative, 3) aromatic amine compounds such as a triarylamine derivative, and a fused polycyclic aromatic amine derivative, and the like are used.

### Electron-Transporting Layer

The electron-transporting layer is a layer containing a substance having a high electron-transporting property. For the electron-transporting layer, 1) metal complexes such as an aluminum complex, a beryllium complex, and a zinc complex; 2) heteroaromatic complexes such as an imidazole derivative, a benzimidazole derivative, an azine derivative, a carbazole derivative, and a phenanthroline derivative; and 3) polymer compounds can be used.

### Electron-Injecting Layer

The electron-injecting layer is a layer containing a substance having a high electron-injecting property. For the electron-injecting layer, compounds which can be used in the electron-transporting layer described above, lithium (Li), ytterbium (Yb), lithium fluoride (LiF), cesium fluoride (CsF), calcium fluoride (CaF₂), metal complex compounds such as 8-hydroxyquinolinolato-lithium (Liq), alkali metals, alkaline earth metals and compounds thereof such as lithium oxide (LiOₓ) can be used.

### Cathode

For the cathode, metals, alloys, electrically conductive compounds, mixtures thereof, and the like having a small work function (specifically, 3.8 eV or lower) are preferably used. Specific examples of such cathode materials include elements belonging to Group 1 or Group 2 of the Periodic Table of the Elements, i.e., alkali metals such as lithium (Li) and cesium (Cs), alkaline earth metals such as magnesium (Mg), calcium (Ca) and strontium (Sr), and alloys containing these metals (e.g., MgAg and AlLi); rare earth metals such as europium (Eu) and ytterbium (Yb), and alloys containing these metals.

In the organic EL device according to an aspect of the invention, the methods for forming the respective layers are not particularly limited. Conventionally-known methods for forming each layer according to a vacuum deposition process, a spin coating process and the like can be used. The respective layers such as the emitting layer can be formed by a known method such as a vacuum deposition process, a molecular beam deposition process (MBE process), or an application process such as a dipping process, a spin coating process, a casting process, a bar coating process, or a roll coating process, using a solution prepared by dissolving a material in a solvent.

In the organic EL device according to an aspect of the invention, the thickness of each layer is not particularly limited, but is generally preferable that the thickness be in the range of several nm to 1 μm in order to suppress defects such as pinholes, to suppress applied voltages to be low, and to enhance luminous efficiency.

### Electronic Apparatus

The electronic apparatus according to an aspect of the invention is characterized in that the organic EL device according to an aspect of the invention is equipped with.

Specific examples of the electronic apparatus include display components such as an organic EL panel module, and the like; display devices for a television, a cellular phone, a personal computer, and the like; and emitting devices such as a light, a vehicular lamp, and the like.

### EXAMPLES

Hereinafter, Examples according to the invention will be described. The invention is not limited in any way by these Examples.

### Compounds

Compounds represented by the formula (1) used for fabricating the organic EL devices of Examples 1 to 4 and Comparative Example 1 are shown below.

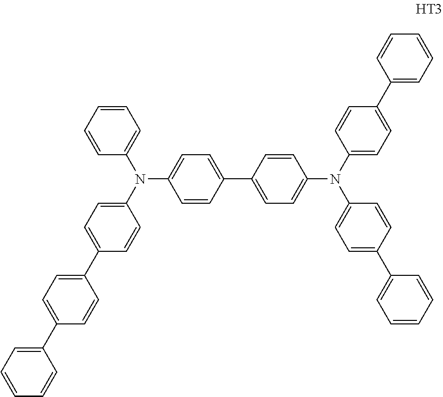 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

Compounds represented by the formula (11) used for fabricating the organic EL devices of Examples 1 to 4 and Comparative Examples 2 to 5 are shown below.

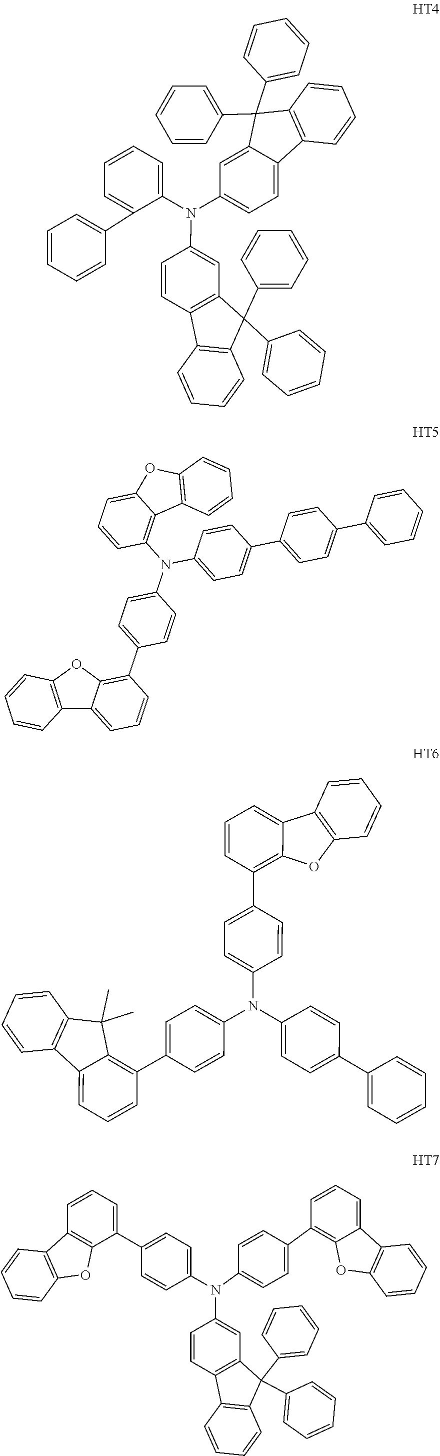 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(-c3ccc(N(c4ccc(-c5cccc6c5oc5ccccc56)cc4)c4cccc5oc6ccccc6c45)cc3)cc2)cc1 ; CC1(C)c2ccccc2-c2cccc(-c3ccc(N(c4ccc(-c5ccccc5)cc4)c4ccc(-c5cccc6c5oc5ccccc56)cc4)cc3)c21 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1]

Other compounds used for fabricating the organic EL devices of Examples 1 to 4 and Comparative Examples 1 to 5 are shown below.

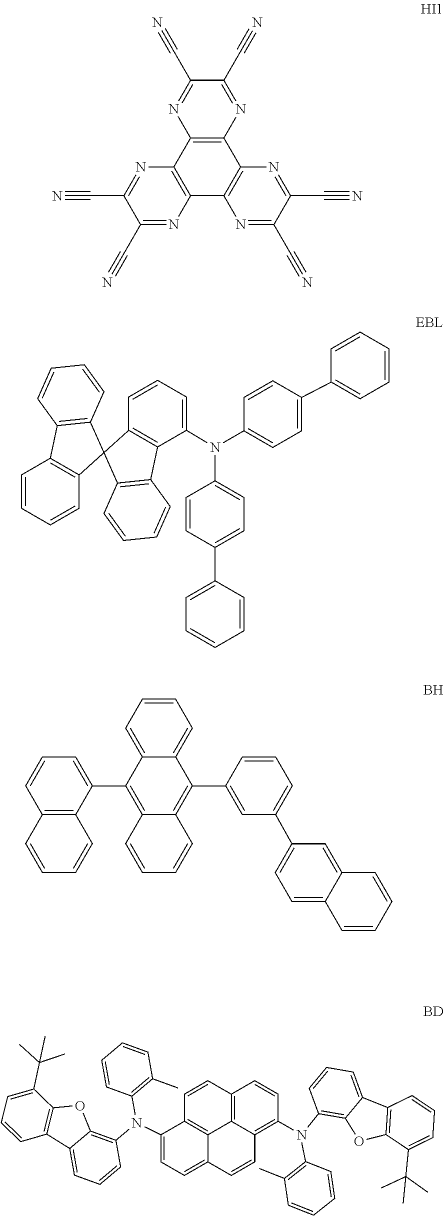

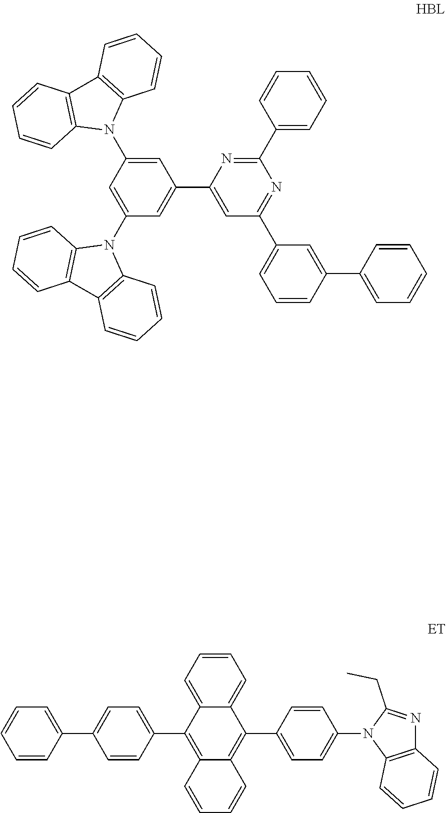 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; CCc1nc2ccccc2n1-c1ccc(-c2c3ccccc3c(-c3ccc(-c4ccccc4)cc3)c3ccccc23)cc1]

The ionization potentials (Ip) (eV) of the compound represented by the formula (1) and the compounds represented by the formula (11) (hole-transporting material) were determined as follows, and is shown in Table 1 below.

The ionization potential (Ip) means an energy required for removing an electron from a compound of a host material to ionize the compound. For example, the ionization potential is a value measured by an Ultraviolet Photoemission Yield Spectroscopy meter (AC-3, manufactured by Riken Keiki Co., Ltd.). In Examples, the ionization potential was measured using an Atmospheric Photoemission Yield Spectroscopy meter (AC-3, manufactured by Riken Keiki Co., Ltd.). Specifically, a material was irradiated with light, and the quantity of electrons generated by charge-separation was measured.

TABLE 1

| Hole-transporting material | Ionization potential (eV) |
|---|---|
| HT3 | 5.54 |
| HT4 | 5.61 |
| HT5 | 5.71 |
| HT6 | 5.73 |
| HT7 | 5.62 |

### Fabrication of Organic EL Device

An organic EL device was fabricated and evaluated as follows.

### Example 1

A 25 mm×75 mm×1.1 mm-thick glass substrate with an ITO transparent electrode (anode) (manufactured by GEOMATEC Co., Ltd.) was subjected to ultrasonic cleaning in isopropyl alcohol for 5 minutes, and then subjected to UV-ozone cleaning for 30 minutes. The thickness of the ITO film was 130 nm.

The glass substrate with a transparent electrode line after being cleaned was mounted onto a substrate holder in a vacuum vapor deposition apparatus, and Compound HI1 was deposited on a surface on the side on which the transparent electrode line was formed so as to cover the transparent electrode to form a hole-injecting layer having a thickness of 5 nm.

Next, on the hole-injecting layer, Compound HT3 (first hole-transporting material) and Compound HT4 (second hole-transporting material) were co-deposited at a proportion of 70% by mass: 30% by mass to form a hole-transporting layer (first layer) having a film thickness of 80 nm.

Then, on this hole-transporting layer, Compound EBL was deposited to form an electron-blocking layer (second hole-transporting layer) having a film thickness of 10 nm.

Next, on this electron-blocking layer, Compound BH (host material) and Compound BD (dopant material) were co-deposited such that a proportion of Compound BD became 2% by mass to form an emitting layer having a film thickness of 25 nm.

Next, Compound HBL was deposited on this emitting layer to form a first electron-transporting layer having a film thickness of 10 nm.

Next, Compound ET was deposited on this first electron-transporting layer to form a second electron-transporting layer having a film thickness of 15 nm.

Next, lithium fluoride (LiF) was deposited on this second electron-transporting layer to form an electron-injecting electrode (cathode) having a film thickness of 1 nm.

Then, on this electron-injecting electrode, metal aluminum (Al) was deposited to form a metal Al cathode having a film thickness of 80 nm.

The device configuration of the organic EL device of Example 1 is shown in a simplified manner as follows.

ITO(130)/HI1(5)/HT3:HT4(80, 70%:30%)/EBL(10)/BH:BD(25, 98%:2%)/HBL(10)/ET(15)/LiF(1)/Al (80)

The numerical values in parentheses indicate the thickness of the film (unit: nm). Also, the numerical values shown in terms of the percentage (% by mass) in parentheses, indicate the percentages of the first compound, and the second compound in the layers.

### Evaluation of Organic EL Device

For each of the resulting organic EL devices, the driving voltage V (eV), the external quantum efficiency EQE (%) and the device lifetime LT95 (hr) were determined by the following methods.

### Driving Voltage V(eV)

Initial characteristics of the obtained organic EL device was measured under conditions of driving at a constant current of 10 mA/cm² of DC (direct current) at room temperature. The measurement results of the driving voltage are shown in Table 2.

### External Quantum Efficiency EQE (%)

Voltage was applied to the resulting organic EL device to be 10 mA/cm² in current density, thereby measuring an EL emission spectrum by using Spectroradiometer CS-1000 (manufactured by Konica Minolta, Inc.). External quantum efficiency (EQE) (%) was calculated based on the obtained spectral radiance spectrum.

### Device Lifetime LT95(hr)

A voltage was applied to the obtained organic EL device so that the current density became 50 mA/cm², and the time until the luminance became 95% of the initial luminance (LT95@50 mA/cm²) was measured, and the result of the lifetime LT95 (hr) is shown in Table 2.

### Examples 2 to 4

Organic EL devices were fabricated and evaluated in the same manner as in Example 1, except that each of the first and second hole-transporting materials described in Tables 3 to 5 below were used. The results are shown in Tables 3 to 5.

### Comparative Examples 1 to 5

Organic EL devices were fabricated and evaluated in the same manner as in Example 1, except that the hole-transporting material described in Tables 2 to 5 below was used. The results are shown in Tables 2 to 5.

TABLE 2

| | | Hole- | | | |
|---|---|---|---|---|---|
| | Material | transporting | | | |
| | of the hole- | material | V | EQE | LT95 |
| | injecting | of the | (50 mA/ | (10 mA/ | (50 mA/ |
| | layer | first layer | cm²) | cm²) | cm²) |
| Example 1 | HI1 | HT3:HT4 | 9.2 | 6.9 | 126 |
| Comparative | HI1 | HT3 | 9.2 | 6.5 | 53 |
| Example 1 | | | | | |
| Comparative | HI1 | HT4 | 5.8 | 18.0 | 75 |
| Example 2 | | | | | |

TABLE 3

| | | Hole- | | | |
|---|---|---|---|---|---|
| | Material | transporting | | | |
| | of the hole- | material | V | EQE | LT95 |
| | injecting | of the | (50 mA/ | (10 mA/ | (50 mA/ |
| | layer | first layer | cm²) | cm²) | cm²) |
| Example 2 | HI1 | HT3:HT5 | 9.3 | 7.3 | 153 |
| Comparative | HI1 | HT3 | 9.2 | 6.5 | 53 |
| Example 1 | | | | | |
| Comparative | HI1 | HT5 | 4.6 | 19.1 | 3 |
| Example 3 | | | | | |

TABLE 4

| | | Hole- | | | |
|---|---|---|---|---|---|
| | Material | transporting | | | |
| | of the hole- | material | V | EQE | LT95 |
| | injecting | of the | (50 mA/ | (10 mA/ | (50 mA/ |
| | layer | first layer | cm²) | cm²) | cm²) |
| Example 3 | HI1 | HT3:HT6 | 9.3 | 7.2 | 168 |
| Comparative | HI1 | HT3 | 9.2 | 6.5 | 53 |
| Example 1 | | | | | |
| Comparative | HI1 | HT6 | 4.3 | 19.5 | 1 |
| Example 4 | | | | | |

TABLE 5

| | | Hole- | | | |
|---|---|---|---|---|---|
| | Material | transporting | | | |
| | of the hole- | material | V | EQE | LT95 |
| | injecting | of the | (50 mA/ | (10 mA/ | (50 mA/ |
| | layer | first layer | cm²) | cm²) | cm²) |
| Example 4 | HI1 | HT3:HT7 | 9.2 | 6.8 | 115 |
| Comparative | HI1 | HT3 | 9.2 | 6.5 | 53 |
| Example 1 | | | | | |
| Comparative | HI1 | HT7 | 5.9 | 17.5 | 60 |
| Example 5 | | | | | |

From the results of Tables 2 to 5, it can be seen that the devices of Examples 1 to 4 using in the first layer (hole-transporting layer), the first hole-transporting material of the compound represented by the formula (1) and the second hole-transporting material have remarkably increased lifetime as compared with the devices of Comparative Examples 1 to 5 using in the corresponding layer, only one of the two materials.

In addition, although the devices of Comparative Examples which used only the compound used as the first hole-transporting material in the first layer of Examples have a driving voltage to the same degree of those of the devices of Examples, the devices of Comparative Examples have a low luminous efficiency and a short device lifetime. Although the devices of Comparative Examples which used only the compound of the second hole-transporting material used in the first layer of Examples have a lower driving voltage and a higher luminous efficiency as compared with the devices of Examples, the devices of Comparative Examples have a short device lifetime. It can be seen that, by using these two types of hole-transporting material together in the first layer (hole-transporting layer), while keeping the same or deceased driving voltage and increased luminous efficiency as the devices of Comparative Examples using only the first hole-transporting material, significantly increased device lifetime is obtained.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

1. An organic electroluminescence device comprising a cathode, an anode, and an organic layer disposed between the cathode and the anode, wherein
he organic layer comprises an emitting layer and a first layer,
the first layer is disposed between the anode and the emitting layer,
the first layer comprises a first hole-transporting material represented by the following formula (1) and a second hole-transporting material represented by the following formula (11): 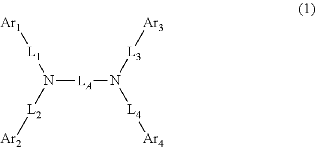
wherein in the formula (1),
L_{A} is
a substituted or unsubstituted arylene group including 6 to 50 ring carbon atoms, or
a substituted or unsubstituted divalent heterocyclic group including 5 to 50 ring atoms;
L₁ to L₄ are independently a single bond or a linking group;
when each of L₁ to L₄ is a linking group, the linking group is
a substituted or unsubstituted arylene group including 6 to 50 ring carbon atoms, or
a substituted or unsubstituted divalent heterocyclic group including 5 to 50 ring atoms; and
Ar₁ to Ar₄ are independently
a substituted or unsubstituted aryl group including 6 to 50 ring carbon atoms, or
a substituted or unsubstituted monovalent heterocyclic group including 5 to 50 ring atoms; 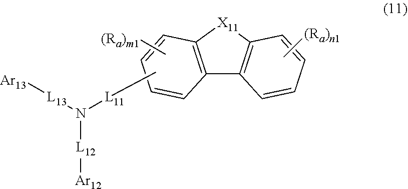
wherein in the formula (11),
L₁₁ to L₁₃ are independently a single bond or a linking group;
when each of L₁₁ to L₁₃ is a linking group, the linking group is
a substituted or unsubstituted arylene group including 6 to 50 ring carbon atoms, or
a substituted or unsubstituted divalent heterocyclic group including 5 to 50 ring atoms;
each set of L₁₁ and L₁₂, L₁₁ and L₁₃, L₁₁ and Ar₁₂, and L₁₁ and Ar₁₃ does not form a heterocycle containing N by bonding with each other;
Ar₁₂ and Ar₁₃ are independently
a substituted or unsubstituted aryl group including 6 to 50 ring carbon atoms, or
a substituted or unsubstituted monovalent heterocyclic group including 5 to 50 ring atoms;
X₁₁ is O, S, or C(R₁₁)(R₁₂);
R₁₁ and R₁₂ form a substituted or unsubstituted, saturated or unsaturated ring by bonding with each other, or do not form the ring;
R₁₁ and R₁₂ which do not form the ring are independently a hydrogen atom,
a substituted or unsubstituted aryl group including 6 to 50 ring carbon atoms, or
a substituted or unsubstituted monovalent heterocyclic group including 5 to 60 ring atoms;
Rₐ is
a substituted or unsubstituted alkyl group including 1 to 50 carbon atoms,
a substituted or unsubstituted aryl group including 6 to 50 ring carbon atoms, or
a substituted or unsubstituted monovalent heterocyclic group including 5 to 50 ring atoms;
m1 is an integer of 0 to 3; when ml is 2 or more, two or more Rₐ's are the same as or different from each other; and
n1 is an integer of 0 to 4; and when n1 is 2 or more, two or more Rₐ's are the same as or different from each other.

2. The organic electroluminescence device according to claim 1, wherein L_{A} in the formula (1) is a substituted or unsubstituted arylene group including 6 to 50 ring carbon atoms.

3. The organic electroluminescence device according to claim 1, wherein L_{A} in the formula (1) is a group selected from the group consisting of
a substituted or unsubstituted phenylene group,
a substituted or unsubstituted biphenylene group,
a substituted or unsubstituted terphenylene group,
a substituted or unsubstituted quaterphenylene group, and
a substituted or unsubstituted naphthylene group.

4. The organic electroluminescence device according to claim 1, wherein the compound represented by the formula (1) is a compound represented by the following formula (1-1): 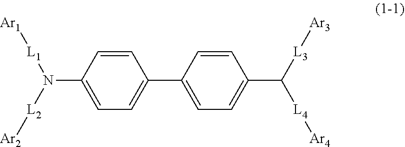
wherein in the formula (1-1), L₁ to L₄ and Ar₁ to Ar₄ are as defined in the formula (1).

5. The organic electroluminescence device according to claim 1, wherein Ar₁ to Ar₄ in each of the formula (1) and the formula (1-1) are independently a substituted or unsubstituted aryl group including 6 to 50 ring carbon atoms.

6. The organic electroluminescence device according to claim 1, wherein Ar₁ to Ar₄ in each of the formula (1) and the formula (1-1) are independently a group selected from the group consisting of
a substituted or unsubstituted phenyl group,
a substituted or unsubstituted biphenyl group,
a substituted or unsubstituted terphenyl group,
a substituted or unsubstituted quarterphenyl group,
a substituted or unsubstituted naphthyl group,
a substituted or unsubstituted fluorenyl group,
a substituted or unsubstituted anthryl group,
a substituted or unsubstituted 9,9′-spirobifluorenyl group,
a substituted or unsubstituted benzofluorenyl group,
a substituted or unsubstituted phenanthryl group, and
a substituted or unsubstituted benzophenanthryl group.

7. The organic electroluminescence device according to claim 1, wherein Ar₁ to Ar₄ in each of the formula (1) and the formula (1-1) are independently a group selected from the group consisting of
an unsubstituted phenyl group,
an unsubstituted biphenyl group,
an unsubstituted terphenyl group,
an unsubstituted quarterphenyl group,
an unsubstituted naphthyl group,
an unsubstituted fluorenyl group,
an unsubstituted anthryl group,
an unsubstituted 9,9′-spirobifluorenyl group,
an unsubstituted benzofluorenyl group,
an unsubstituted phenanthryl group, and
an unsubstituted benzophenanthryl group.

8. The organic electroluminescence device according to claim 1, wherein L₁₁ to L₁₃ in the formula (11) are independently a single bond, or
a substituted or unsubstituted arylene group including 6 to 50 ring carbon atoms.

9. The organic electroluminescence device according to claim 1, wherein L₁₁ to L₁₃ in the formula (11) are independently a single bond or a group selected from the group consisting of
a substituted or unsubstituted phenylene group,
a substituted or unsubstituted biphenylene group,
a substituted or unsubstituted terphenylene group,
a substituted or unsubstituted quaterphenylene group, and
a substituted or unsubstituted naphthylene group.

10. The organic electroluminescence device according to claim 1, wherein L₁₁ to L₁₃ in the formula (11) are independently a single bond or
an unsubstituted phenylene group.

11. The organic electroluminescence device according to claim 1, wherein Ar₁₂ and Ar₁₃ in the formula (11) are independently a group selected from the group consisting of
a substituted or unsubstituted phenyl group,
a substituted or unsubstituted naphthyl group,
a substituted or unsubstituted fluorenyl group,
a substituted or unsubstituted 9,9′-spirobifluorenyl group,
a substituted or unsubstituted benzofluorenyl group,
a substituted or unsubstituted phenanthryl group,
a substituted or unsubstituted benzophenanthryl group,
a substituted or unsubstituted dibenzofuranyl group, and
a substituted or unsubstituted dibenzothiophenyl group.

12. The organic electroluminescence device according to claim 1, wherein Rₐ in the formula (11) is a substituted or unsubstituted aryl group including 6 to 50 ring carbon atoms.

13. The organic electroluminescence device according to claim 1, wherein either or both of m1 and n1 in the formula (11) are 0.

14. The organic electroluminescence device according to claim 1, wherein the first layer contains the first hole-transporting material and the second hole-transporting material in a mass ratio of 80:20 to 20:80.

15. An electronic apparatus, equipped with the organic electroluminescence device according to claim 1.
